(19) United States
(12) Patent Application Publication
(10) Pub. No.: US 2024/0196058 A1
(43) Pub. Date: Jun. 13, 2024

(54) SYSTEMS AND METHODS INVOLVING ARTIFICIAL INTELLIGENCE AND CLOUD TECHNOLOGY FOR EDGE AND SERVER SOC

(71) Applicant: Uniquify, Inc., Santa Clara, CA (US)

(72) Inventor: Joshua Jungho LEE, San Jose, CA (US)

(21) Appl. No.: 18/288,159

(22) PCT Filed: May 3, 2022
(86) PCT No.: PCT/US2022/027496

§ 371 Date: Oct. 24, 2023

Related U.S. Application Data
(60) Provisional application No. 63/184,576, filed on May 5, 2021.
(60) Provisional application No. 63/184,630, filed on May 5, 2021.

(30) Foreign Application Priority Data
Apr. 29, 2022 (WO) PCT/US2022/027035

(51) Int. Cl. H04N 21/462; H04N 21/232; H04N 21/435; H04N 21/44; H04N 21/466; H04N 21/854

(52) U.S. Cl. CPC H04N 21/4622; H04N 21/232; H04N 21/435; H04N 21/44008; H04N 21/4666; H04N 21/854

(57) ABSTRACT

Aspects of the present disclosure involve systems, methods, computer instructions, and an edge system involving a memory configured to store an object detection/classification model in a form of a trained neural network represented by one or more log quantized parameter values, the object detection/classification model configured to classify one or more objects on image data through one or more neural network operations according to the log quantized parameter values of the trained neural network; and a system on chip (SoC) or equivalent circuitry/hardware/computer instructions thereof configured to intake the image data; execute one or more trained neural network models through the one or more neural network operations in connection with the image data; add one or more overlays to the image data based on the classified one or more objects from the image data; and provide the image data with the added overlays as output.

### CROSS REFERENCE TO RELATED APPLICATION(S)

This application claims the benefit of and priority to U.S. Provisional Application Ser. No. 63/184,576, entitled “Systems and Methods Involving Artificial Intelligence and Cloud Technology for Edge and Server SOC” and filed on May 5, 2021, U.S. Provisional Application Ser. No. 63/184,630, entitled “Systems and Methods Involving Artificial Intelligence and Cloud Technology for Edge and Server SOC” and filed on May 5, 2021, and PCT Application no. PCT/US22/27035, entitled “IMPLEMENTATIONS AND METHODS FOR PROCESSING NEURAL NETWORK IN SEMICONDUCTOR HARDWARE” and filed on Apr. 29, 2022, the disclosures of which are expressly incorporated by reference herein in its entirety.

### BACKGROUND

### Field

The present disclosure is generally related to artificial intelligence systems, and more specifically, to systems and methods involving artificial intelligence (AI) and cloud technology in hardware and software.

### Related Art

There are many forms of digital content. The term “digital content” may comprise any visual, audible, and/or language content that consumers digest. For example, digital content may be comprised of images, videos, sound, and/or texts. Delivery mechanisms for digital content may include, ethernet, cell phone network, satellite, cables, internet, WIFI, and/or the like. Devices that may be used to deliver the content to consumers may include TV, mobile phone, automobile display, surveillance camera display, personal computer (PC), tablet, augmented reality (AR) devices, virtual reality (VR) devices, and various internet of thing (IoT) devices. Digital content can be divided into “real-time” content, such as live sporting events or other live events, and “prepared” content such as movies, sitcoms, or other pre-recorded or non-live events.

Both “real-time” and “prepared” digital contents are presented to consumers without any further processing or annotation. FIG. 1 illustrates an example of “real-time” content which may comprise a sporting event (e.g., basketball game). The digital content may be displayed on a display device (e.g., TV) without further processing or relevant annotation. In some instances, the digital content may include annotations related to the content, such as but not limited to, score of the teams involved in the sporting event or advertisement, but such annotations are included a priori by the entity that is broadcasting the digital content to consumers. However, such annotations are not the result of processing the digital content and finding the relevant annotation for the content.

### SUMMARY

Example implementations described herein are directed to a novel approach to process digital content to gain intelligent information about the content, such as information that comes from object detection, object classification, facial recognition, text detection, natural language processing, and connect/supplement appropriate and relevant information found in the cloud/internet/system/database/people with the parts of the digital content that is processed to be ready to be presented to the consumers. The example implementations provide a method of connecting/annotating processed digital content with the relevant and appropriate information found in the cloud/internet as implemented in hardware, software, or some combination thereof. The proposed example implementations may allow for interaction between the consumer and the processed digital content and annotated cloud/internet information which may enhance the consumer experience while consuming the digital content.

Example implementations described herein may process visual and/or audio digital content. For example, processing digital content may entail classifying, identifying, and/or detecting people, objects, concepts, scenes, text, and/or language in visual and audio digital content. In another example, digital content may be processed to convert audio content to text and identify relevant information within the converted text. The classification or identification process may include the processing of an image, video, sound, and/or language within the digital content to identify one or more people (e.g., presence or identity), a type of object (e.g., car, boat, etc.), meaning of text or language, any concept, or any scene. For example, various AI models, neural network models, and/or machine learning models may be utilized to process and classify images, videos, and/or language within digital content, but other models or algorithms may be used. The digital content may be processed to obtain useful information about the content to connect any appropriate information from the cloud or internet and annotate the found information to the visual and audio digital content that is processed, which may then be ready to be presented to consumers on a device that can display visual digital content and play audio digital content. The cloud or internet may include any information present in any server, any form of database, any computer memory, any storage device, or any consumer devices.

In example implementations described herein, a network device (e.g., server or hub) may be configured to process digital content to connect the relevant cloud information related to the digital content. The network device may utilize AI models, neural network models, and/or machine learning models to process the digital content to detect and/or analyze the digital content for items within the digital content that are relevant or interesting for the viewers. The network device may provide the processed digital content to an edge device having a display device. The network device may supplement the digital content with the relevant cloud/internet information related to the digital content such that at least some of the cloud information may be displayed along with the digital content per viewers' direction. Supplementing the digital content with the relevant cloud/internet information related to the digital content may enhance the consumer experience while consuming the digital content.

In example implementations described herein, an edge device having a display device may be configured to receive a stream of digital content from a network device. The edge device may display the digital content supplemented with cloud information as processed by the network device. The edge device may also be configured to process the stream of digital content, in the absence of the network device. For example, the edge device may process the digital content to identify and detect people, objects, texts, and scenes to gain the relevant and supplemental information to the content from the cloud and internet. The edge device may supplement the digital content with the relevant information related to the digital content from the cloud/internet and present the supplemented digital content to consumers/viewers. The edge device may allow for a customized interaction of the viewers and the digital content supplemented with the cloud information to allow for an interactive experience for viewers.

Aspects of the present disclosure can involve an edge system for processing digital content comprising a memory configured to store an object detection model in a form of a trained neural network represented by one or more log quantized parameter values, the object detection model configured to classify one or more objects on image data through one or more neural network operations according to the log quantized parameter values of the trained neural network; and a system on chip (SoC), configured to intake the image/audio data; execute one or more trained neural network models through the one or more neural network operations in connection with the image data; add one or more overlays to the image data based on the classified one or more objects from the image/audio data; and provide the image/audio data with the added overlays as output.

Aspects of the present disclosure can involve a television-implemented method for processing digital content, comprising intaking a television broadcast; executing one or more trained neural network models through one or more neural network operations of a trained neural network in connection with the television broadcast; adding one or more overlays to the television data based on one or more classified objects from the image data; and displaying the television data with the added overlays on a display of the television.

Aspects of the present disclosure can involve a computer program storing instructions for processing digital content, comprising a memory configured to store an object detection model in a form of a trained neural network represented by one or more log quantized parameter values, the object detection model configured to classify one or more objects on image data through one or more neural network operations according to the log quantized parameter values of the trained neural network; and a system on chip (SoC), configured to intake the image data; execute one or more trained neural network models through the one or more neural network operations in connection with the image data; add one or more overlays to the image data based on the classified one or more objects from the image data; and provide the image data with the added overlays as output.

Aspects of the present disclosure can involve an edge system for processing digital content, comprising means for intaking a television broadcast; means for executing one or more trained neural network models through one or more neural network operations of a trained neural network in connection with the television broadcast; means for adding one or more overlays to the television data based on one or more classified objects from the image data; and means for displaying the television data with the added overlays on a display of the television.

Aspects of the present disclosure can include an edge system, which can involve a memory configured to store one or more trained artificial intelligence/neural network (AI/NN) models AI/neural network models; and a system on chip (SoC), configured to intake broadcasted or streaming digital content; process the broadcasted or streaming digital content with the one or more trained AI/NN models; add one or more supplemental content retrieved from another device to the broadcasted or streaming digital content based on the processing of the broadcasted or the streaming digital content with the one or more trained AI/NN models; and provide the broadcasted or streaming digital content with the supplemental content retrieved from another device as output.

Aspects of the present disclosure can include an edge system, which can involve memory means for storing one or more trained artificial intelligence/neural network (AI/NN) models AI/neural network models; means for intaking broadcasted or streaming digital content; process the broadcasted or streaming digital content with the one or more trained AI/NN models; means for adding supplemental content retrieved from another device to the broadcasted or streaming digital content based on the processing of the broadcasted or the streaming digital content with the one or more trained AI/NN models; and means for providing the broadcasted or streaming digital content with the supplemental content retrieved from another device as output.

Aspects of the present disclosure can include a method for an edge system, which can involve intaking broadcasted or streaming digital content; processing the broadcasted or streaming digital content with one or more trained AI/NN models; adding retrieved supplemental content retrieved to the broadcasted or streaming digital content based on the processing of the broadcasted or the streaming digital content with the one or more trained AI/NN models; and providing the broadcasted or streaming digital content with the supplemental content retrieved from another device as output.

Aspects of the present disclosure can include a computer program for an edge system, which can involve instructions including intaking broadcasted or streaming digital content; processing the broadcasted or streaming digital content with one or more trained AI/NN models; adding retrieved supplemental content retrieved to the broadcasted or streaming digital content based on the processing of the broadcasted or the streaming digital content with the one or more trained AI/NN models; and providing the broadcasted or streaming digital content with the supplemental content retrieved from another device as output. The instructions can be stored on a non-transitory computer readable medium and executed by one or more processors.

### BRIEF DESCRIPTION OF DRAWINGS

FIG. 1 illustrates an example of digital content in accordance with the related art.

FIGS. 2A and 2B illustrate an example of digital content supplemented with the relevant cloud/internet information by an AI edge SoC, in accordance with an example implementation.

FIGS. 3A and 3B illustrate an example of an overall architecture of an AI edge device, in accordance with an example implementation.

FIGS. 4A and 4B illustrate an example of a digital content processing architecture with neural network processing, in accordance with an example implementation.

FIG. 5 illustrates an overall data path architecture for digital content processing SoC, in accordance with an example implementation.

FIG. 6 illustrates an example of how to sub-divide an input data frame, in accordance with an example implementation.

FIG. 7A illustrates an example of parameter structure for an AI/neural network model, in accordance with an example implementation.

FIG. 7B illustrates an example of an axon (e.g., output of neural network layers) structure, in accordance with an example implementation.

FIGS. 8A-8D illustrate examples of AI edge devices in various systems, in accordance with example implementations.

FIG. 9 illustrates an example of an AI Processing Element (AIPE) for processing the digital content by executing various neural network operations, in accordance with an example implementation.

FIG. 10 illustrates an example of an AIPE array, in accordance with an example implementation.

FIGS. 11A and 11B illustrate an example of a software stack for AI digital content applications using processed digital content, in accordance with an example implementation.

FIGS. 12A-12H illustrate an example of applications that utilize processed digital content, in accordance with an example implementation.

FIG. 13 illustrates an example of processed digital content using detection algorithms, in accordance with an example implementation.

FIG. 14 illustrates an example of processed digital content using people detection algorithm, in accordance with an example implementation.

FIG. 15 illustrates an example of processed digital content using person pose estimation algorithm, in accordance with an example implementation.

FIG. 16 illustrates an example of processed digital content using object and person analysis algorithm, in accordance with an example implementation.

FIG. 17 illustrates an example of processed digital content using text detection and natural language processing algorithm, in accordance with an example implementation.

FIGS. 18A and 18B illustrate an example of processed digital content supplemented with relevant information found in the cloud, internet, system, and any database, in accordance with an example implementation.

FIG. 19 illustrates an example of processed digital content supplemented with relevant information found in the cloud, internet, system, and any database, in accordance with an example implementation.

FIGS. 20A and 20B illustrate an example of processed digital content supplemented with relevant information found in the cloud, internet, system, and any database, in accordance with an example implementation.

FIGS. 21A and 21B illustrate an example of processed digital content supplemented with relevant information from a social media platform, in accordance with an example implementation.

FIGS. 22A and 22B illustrate an example of processed digital content supplemented with relevant information found in an e-commerce platform, in accordance with an example implementation.

FIG. 23 illustrates an example of customized digital content using processed information from the digital content, in accordance with an example implementation.

FIG. 24 illustrates an example of customized digital content using processed information from the digital content, in accordance with an example implementation.

FIG. 25 illustrates an example of various input image pre-processing methods before processing it with various algorithms, in accordance with an example implementation.

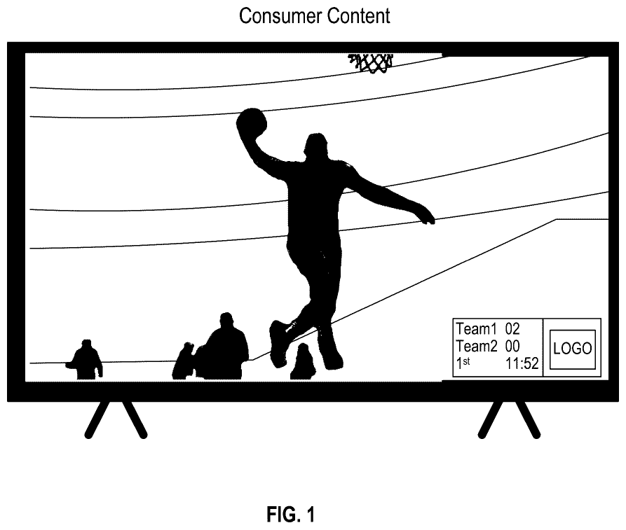

### DETAILED DESCRIPTION

The following detailed description provides details of the figures and example implementations of the present application. Reference numerals and descriptions of redundant elements between figures are omitted for clarity. Terms used throughout the description are provided as examples and are not intended to be limiting. For example, the use of the term “automatic” may involve fully automatic or semi-automatic implementations involving user or administrator control over certain aspects of the implementation, depending on the desired implementation of one of ordinary skill in the art practicing implementations of the present application. Selection can be conducted by a user through a user interface or other input means, or can be implemented through a desired algorithm. Example implementations as described herein can be utilized either singularly or in combination and the functionality of the example implementations can be implemented through any means according to the desired implementations.

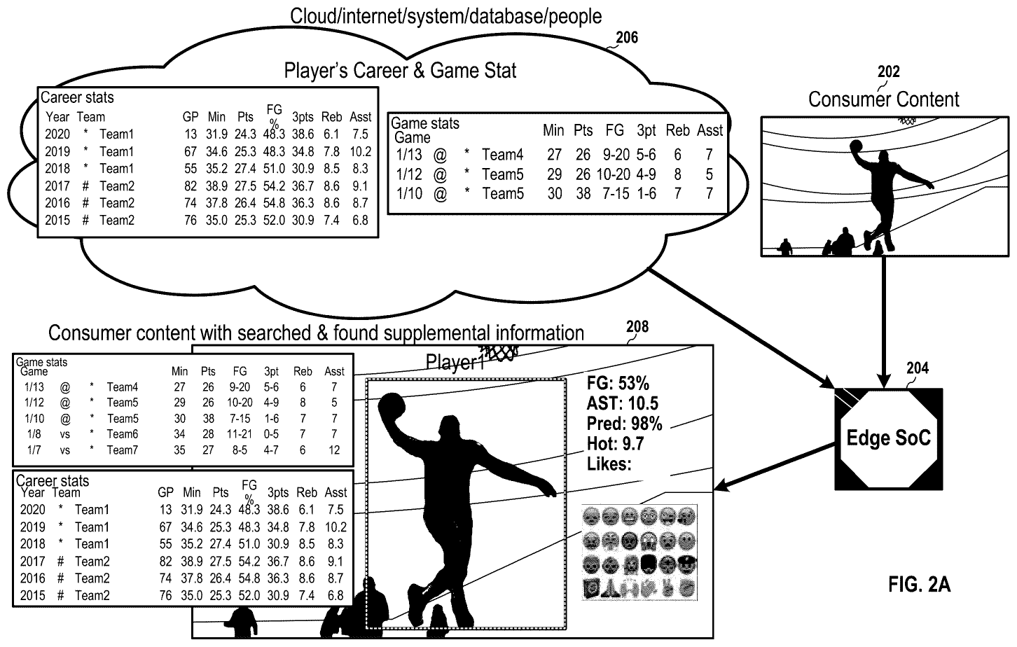

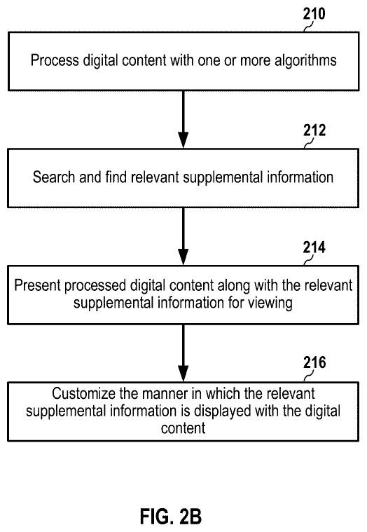

FIGS. 2A and 2B illustrate an example of how digital content is processed and supplemented with relevant information from the cloud, internet, systems, any database, and people (e.g., as input from their devices) in accordance with an example implementation. Specifically, FIG. 2B illustrates a flow of how digital content may be supplemented with relevant information which is used in the example for FIG. 2A. At 210, the flow processes digital content with one or more algorithms. For example, digital content 202 may be provided to an edge SoC device with an artificial intelligence processing element (AIPE) 204 to process the digital content 202. The SoC 204 may be a part of a network or a standalone edge device. (e.g., internet enabled TV or the like). The SoC 204 may receive the digital content 202 and may process the digital content to detect or classify objects within the digital content 202. For example, SoC 204 may process the digital content 202 and detect that the digital content 202 contains basketball players, basketball, and the basket. At 212, the flow may search and find relevant supplemental information. The SoC 204 may search and find the information in the cloud/internet/system/database/people 206 that is related to the processed digital content such as information on the basketball players. For example, the SoC 204 may detect or identify one or more players involved in the real-time sporting event as well as the respective teams. The cloud/internet/system/database/people 206 may include relevant information on the players and the SoC 204 may supplement the digital content 202 with the relevant information from the cloud/internet/system/database/people 206. At 214, the flow may present the processed digital content along with the relevant supplemental information for viewing. The SoC 204 may then provide the digital content annotated with the information from the cloud/internet/system/database/people 206 onto an edge device 208 to display the digital content with the supplemental information to viewers. At 216, the flow may allow for the customization in the manner in which the relevant supplemental information is displayed with the digital content. For example, viewers/consumers may have the option to display any supplemental information together with the digital content such as but not limited to, player identity, real-time statistics of the player, recent statistics of previous games, or season statistics over a period of time or career of the player, player's social media content, e-commerce info related to the players.

Conventional TVs and smart TV's do not have capabilities to process digital content using object detection, object classification, facial recognition, and natural language processing in real time (e.g., 60 frames per second). Conventional TVs and smart TV's may deliver the digital content to consumers either by streaming the content from the internet (e.g., smart TV) or receiving the content via a set-top box. Conventional TVs may also receive and process user inputs (e.g., remote control input, voice input, or camera input).

The AI TV is a TV that processes the digital content, searches relevant information of the processed digital content in the cloud/internet/system/database/people, supplements the digital content with the relevant information found, and present the digital content with the supplemental information to consumers/viewers in real time (60 frames per second). As an example of digital content processing done by the AI TV, the AI TV may classify and identify digital content in real time using neural network models and find the relevant information in the cloud/internet/system/database/people to supplement the content with the found information. The AI TV may process the digital content and run necessary classification and detection algorithms such as various neural network/AI models. The AI TV may also be configured to interact with the consumers/viewers, that allows consumers to choose which supplemental information is to be displayed along with the digital content, the manner in which supplemental information to display, where to display, and when to display the supplemental information. As such, the AI TV may allow the user to have an interactive experience while consuming the digital content.

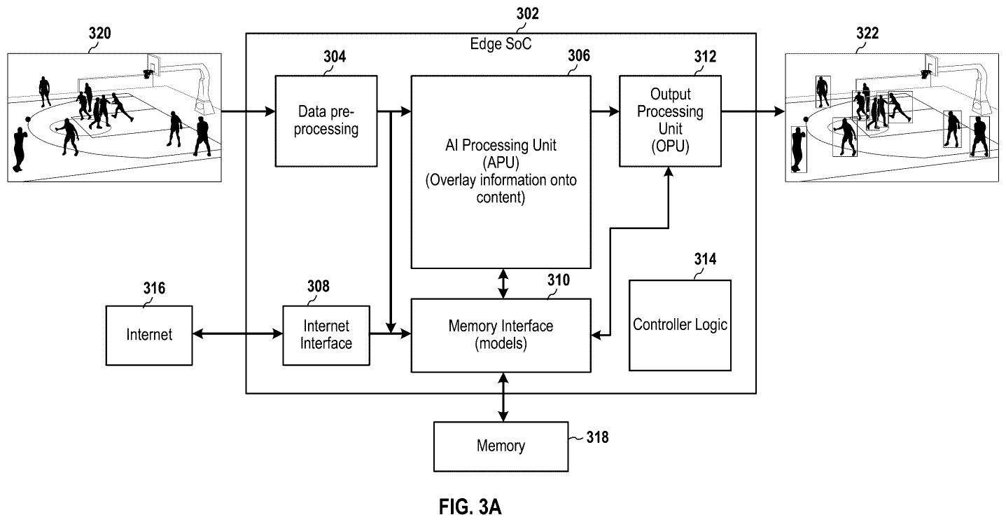

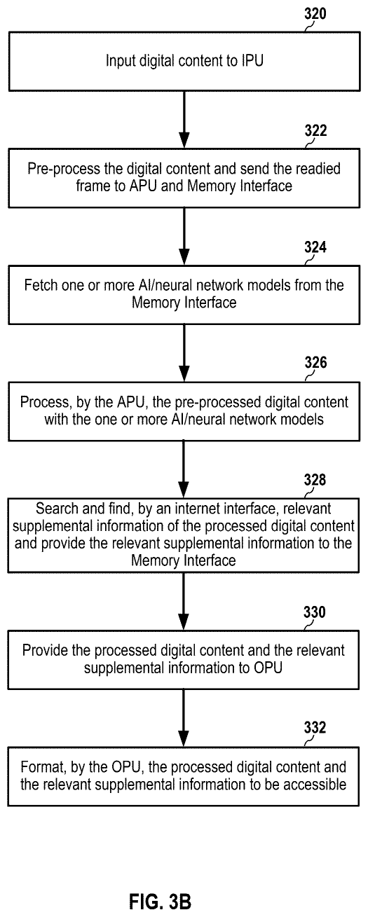

FIGS. 3A and 3B illustrate an overall architecture of AI-Cloud TV SoC, in accordance with an example implementation. Specifically, FIG. 3B illustrates a flow of the overall architecture of the AI-Cloud TV SoC used in the example for FIG. 3A. The AI-Cloud TV SoC 302 may be configured to process the digital content. The AI-Cloud TV SoC 302 may comprise a plurality of elements that are utilized in the processing of the digital content. For example, the AI-Cloud TV SoC 302 may comprise an input/pre-processing unit (IPU) 304, an AI processing unit (APU) 306, an internet interface 308, a memory interface 310, an output processing unit (OPU) 312, and a controller logic 314.

At 320, the flow may input digital content to the IPU. The IPU 304 may receive, as input, the digital content 320. At 322, the flow may pre-process the input digital content and send the readied digital content to the APU and memory interface. The IPU 304 may ready the digital content 320 to be used by the AI Processing Unit and the memory interface. For example, the IPU 304 may receive the digital content 320 as a plurality of frames and audio data, and readies the plurality of frames and audio data to be processed by the APU. The IPU 304 provides the readied digital content 320 to the APU 306. The APU 306 processes the digital content using various neural network models and other algorithms that it gets from the memory via the memory interface. For example, the memory interface 310 includes a plurality of neural network models and algorithms that may be utilized by the APU 306 to process the digital content.

At 324, the flow may fetch one or more AI/neural network models from the memory interface. The memory interface 310 may receive neural network models and algorithms from the cloud/internet/system/database/people 316. For example, the APU may fetch the one or more AI/neural network models form the memory interface. At 326, the flow may process the pre-processed input digital content with the one or more AI/neural network models. For example, the APU 306 may process the pre-processed input digital content with the one or more AI/neural network models. At 328, the flow may search and find relevant supplemental information of the processed digital content and provide the relevant supplemental information to the memory interface. For example, the internet interface 308 may search and find the relevant supplemental information of the processed digital content and provide the relevant supplemental information to the memory interface 310. The memory interface 310 receives, from the internet interface 308, information from the cloud/internet/system/database/people 316 that is relevant to the processed digital content. At 330, the flow may provide the processed digital content and the relevant supplemental information to the OPU. The information from the cloud/internet/system/database/people 316 may be stored in memory 318, and may also be provided to the OPU 312. At 332, the flow may format the processed digital content and the relevant supplemental information to be accessible. The OPU 312 may utilize the information from the cloud/internet/system/database/people 316 to supplement the digital content and may provide the supplemental information and the digital content to the consumers/viewers. The information from the internet may be stored on the memory 318 and may be accessible to the OPU. The OPU may access the information stored on the memory 318 via the memory interface 310. The memory 318 may be internal memory or external memory. The OPU 312 prepares the supplemental information and the digital content 322 to be displayed on a display device. The controller logic 314 may include instructions for operation of the IPU 304, APU 306, the OPU 312, internet interface, and the memory interface 310.

The above procedure may also be utilized to process audio within the digital content 320. For example, the APU 306 may process the audio portion of the digital content and convert the audio to text, and uses natural language processing neural network models or algorithms to process the audio content. The internet interface may find the relevant information from the cloud/internet/system/database/people and create supplemental information, and OPU prepares the supplemental information and the digital content to present to the edge device in a similar manner as discussed above for the plurality of frames.

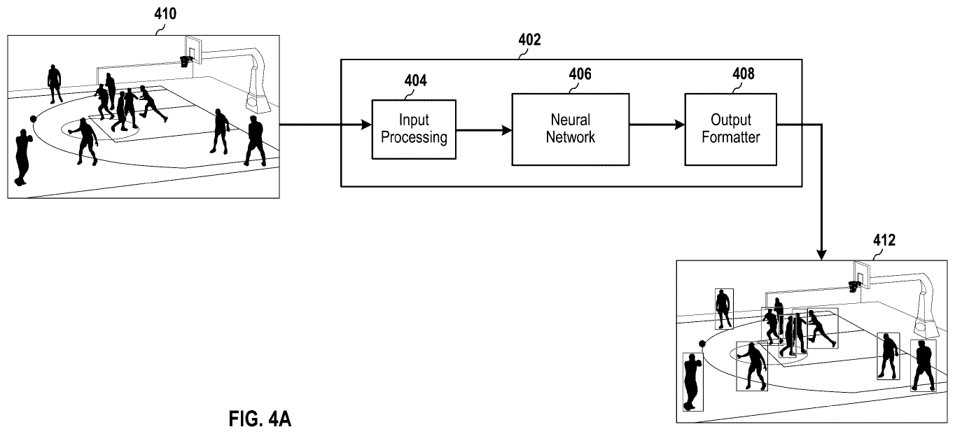

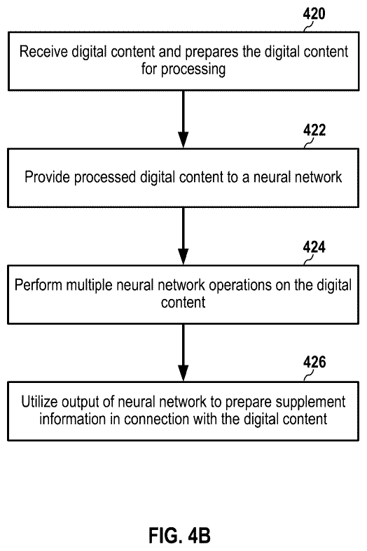

FIGS. 4A and 4B illustrate an example of a general architecture of how to process digital content with neural network/AI models, in accordance with an example implementation. Specifically, FIG. 4B illustrates a flow of the general architecture of the processing of digital content with the neural network/AI models used in the example for FIG. 4A. The AI model architecture 402 includes input processing 404, neural network 406, and output formatter 408. At 420, the flow may receive digital content and prepare the digital content for processing. The AI model architecture 402 may receive digital content 410 as input, where input processing 404 readies the digital content 410. The input processing 404 may prepare video of the digital content 410 as a plurality of frames or may prepare audio of the digital content 410. At 422, the flow may provide the processed digital content to a neural network. For example, the input processing 404 may provide the prepared digital content 410 to the neural network 406. At 424, the flow may perform multiple neural network operations on the digital content. The neural network 406 may perform multiple operations on the digital content 410. For example, the neural network 406 may be configured to detect objects within the processed digital content. For example, the neural network 406 may detect one or more different objects within the digital content, such as but not limited to people, objects, text, or the like.

The neural network 406 can further process the digital content that has been processed prior with various neural network models and algorithms. As an example, if a basketball player is detected with the first neural network model, then the image of the basketball player detected can be processed with other neural network models to detect body parts (face, hands, feet, etc.) or to use facial recognition model to determine who the player is.

In instances where the input processing 404 processes audio of the digital content, the neural network 406 may process the audio input for speech recognition. The neural network 406 may process detected speech using a natural language processing model to understand the speech. The natural language processing may detect or identify relevant information associated with the digital content. The output formatter 408 can find relevant information to the processed digital content in the cloud/internet/system/database/people and supplement the found information with the digital content for the viewers/consumers.

At 426, the flow may utilize the output of the neural network to prepare supplemental information in connection with the digital content. The output formatter 408 may utilize the output of the neural network 406 to get ready supplemental information to the digital content 412 to be displayed. For example, the output formatter 408 may utilize the relevant information obtained from processing the audio of the digital content to display an advertisement, information, or the like, together with the digital content 412 that is related to the relevant information obtained from processing the audio. In another example, the output formatter 408 may utilize the attained information related to the one or more detected people or objects from processing the digital content to get the attained information ready to be used along with the digital content that has been processed (one or more detected people or objects). For example, if the one or more detected people are athletes, then an advertisement for related sporting apparel (e.g., jerseys, uniforms, etc.) may be the supplemental information ready to be used together with the digital content, the athletes. In yet another example, the output formatter 408 may utilize the attained information related to detected objects (other than detected people) from processing the digital content and to get the attained information ready as the supplemental information to the digital content (detected objects) to be used by the viewers/consumers. For example, Output formatter 408 can attain supplemental information such as a relevant advertisement or related information of the detected objects and get them ready to be used by the AI edge device.

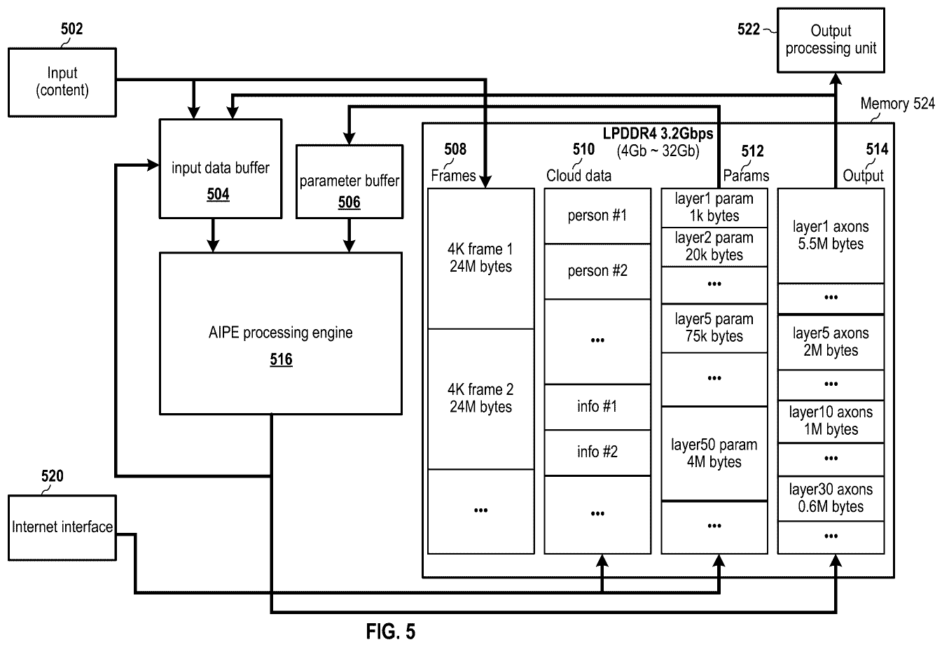

FIG. 5 illustrates an overall data path architecture for digital content processing SoC, in accordance with an example implementation. Input 502 (e.g., digital content) may be received by an input data buffer 504 and memory module 524. In examples involving image data such as television video/broadcast video/streaming video data, such data may be processed into frames 508. A parameter buffer 506 receives parameters from memory module, where the parameters may be obtained from the internet via internet interface 520. The internet interface 520 may also provide cloud data 510, where the cloud data 510 may include information related to the input 502 after it is processed. The parameter from the parameter buffer 506 and the input within the input data buffer 504 are provided to an AIPE processing engine 516. The AIPE processing engine 516 processes the input with the neural network models that is represented by the parameters from the parameter buffer and provides the output to output 514. The output 514 may comprise intermediate results of running the neural network models on the input from the input data buffer 504. The output of the AIPE processing engine 516 may be also provided to the input data buffer 504 and fed back into the AIPE processing engine 516. In some aspects, the parameters from params 512 may be log-quantized parameters. However, in some aspects, the parameters from params 512 are not be log-quantized parameters. The information within output 514 may be provided to the input data buffer 504 and fed back into the AIPE processing engine 516. The output 514 may be provided to an output processing unit 522 to get relevant supplemental information to the input data that is processed from the cloud/internet/system/database/people to be used by the viewers/consumers.

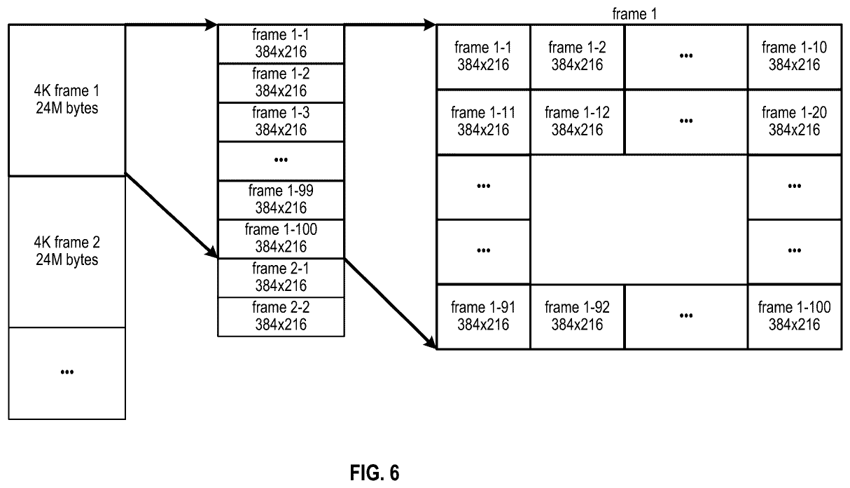

FIG. 6 illustrates an example of how to sub-divide an input data frame, in accordance with an example implementation. The digital content may comprise an input data frame, which may be sub-divided into a plurality of subframes. Each of the plurality of subframes may have a size of 384×216 as an example. The frame of FIG. 6 is an example of how a frame may be sub-divided, but the disclosure is not intended to be limited to the frame of FIG. 6.

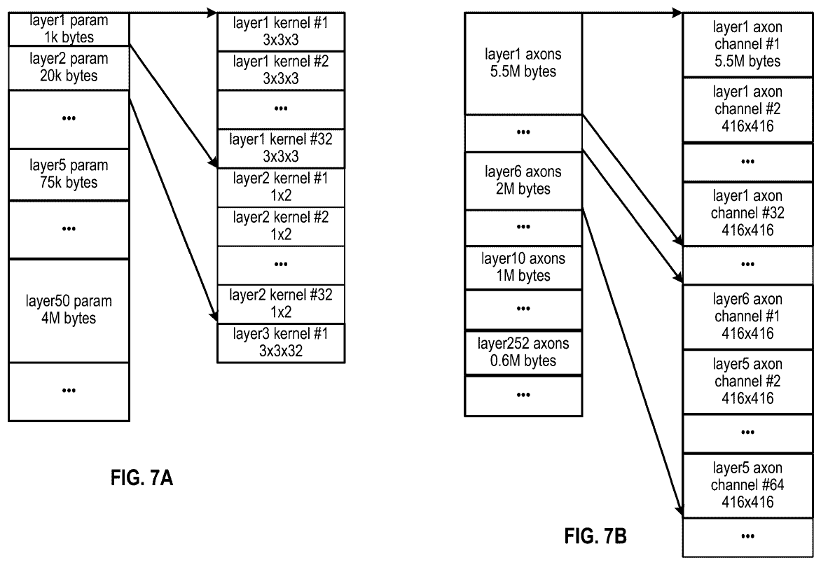

FIG. 7A illustrates an example of parameter structure for an AI/neural network model, in accordance with an example implementation. The parameters may comprise many different sizes (e.g., 1 kbytes, 20 kbytes, 75 kbytes, 4 Mbytes). The parameters in FIG. 7A are organized by each layer of an AI/neural network model. FIG. 7B illustrates an example of an axon (output of a layer) structure, in accordance with an example implementation. The axons may comprise many different sizes (e.g., 5.5 Mbytes, 2 Mbytes, 1 Mbytes, 0.6 Mbytes) depending on the structure of the corresponding layer. The axons in FIG. 7B are organized by the corresponding layer of an AI/neural network model.

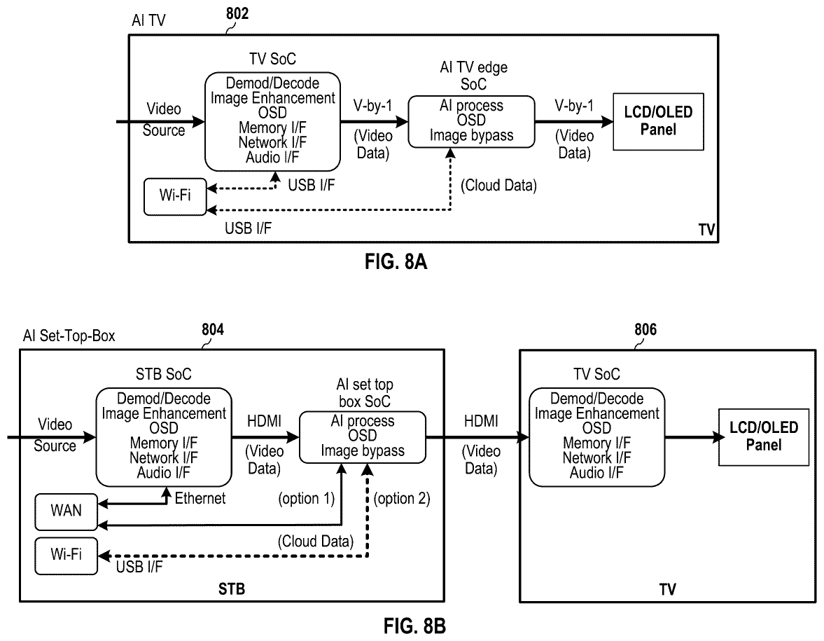

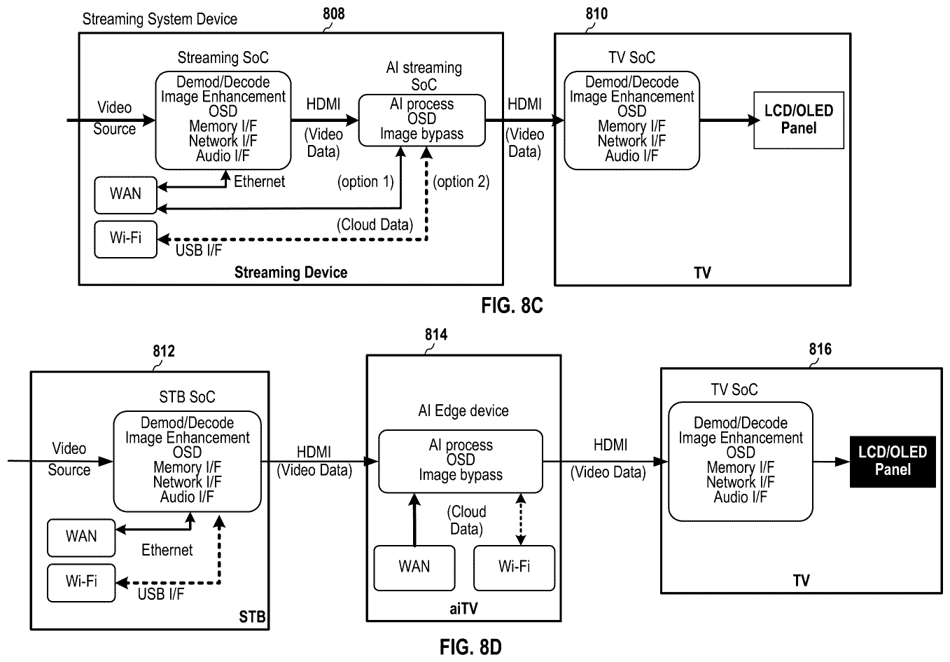

FIGS. 8A-8D illustrate examples of the AI edge devices in various systems, in accordance with example implementations. FIG. 8A provides an example of an AI TV 802 that comprises a TV SoC, an AI TV edge SoC, and a display panel in a fully integrated device. The AI TV 802 includes the AI TV edge SoC that processes the digital content and provides supplemental information to the digital content comprising relevant data/information associated with the digital content attained from the cloud/internet/system/database/people to be used by the AI TV 802. FIG. 8B provides an example of an AI set top box 804 that is an external device that is configured to be connected to a TV 806. The AI set top box 804 may be connected to the TV 806 via an HDMI connection, but other connections may be utilized for connecting the AI set top box 804 and the TV 806. The AI set top box 804 comprises a set top box (STB) SoC and an AI set top box SoC. The AI set top box 804 receives the digital content and processes the digital content and provides, as output, supplemental information to the digital content comprising relevant data/information associated with content the digital attained from the cloud/internet/system/database/people. The supplemental information along with the digital content may be provided to the TV 806 via the HDMI connection. FIG. 8C provides an example of a streaming system device 808 that is an external device configured to be connected to a TV 810. The streaming system device 808 may be connected to the TV 810 via an HDMI connection, but other connections may be utilized for connecting the streaming system device 808 and the TV 810. The streaming system device 808 comprises a streaming SoC and an AI streaming SoC. The streaming system device 808 receives the digital content and processes the digital content and provides, as output, supplemental information to the digital content comprising relevant data associated with the digital content attained from the cloud/internet/system/database/people. The supplemental information along with the digital content may be provided to the TV 810 via the HDMI connection. FIG. 8D provides an example of an AI Edge device 814 that is a stand-alone device. The AI Edge device 814 receives the digital content from a set top box 812 via an HDMI connection and processes the digital content to provide supplemental information to the digital content comprising relevant data associated with the digital content attained from the cloud/internet/system/database/people. The AI Edge device 814 provides the supplemental information along with the digital content to a TV 816 via an HDMI connection.

As described herein, there can be an edge system as illustrated in FIGS. 8A to 8D incorporating the edge SoC as illustrated in FIGS. 3A and 3B, which can involve a memory 318 configured to store one or more trained artificial intelligence/neural network (AI/NN) models AI/neural network models; and a system on chip (SoC) 302, configured to intake broadcasted or streaming digital content (e.g. via IPU 304); process the broadcasted or streaming digital content with the one or more trained AI/NN models (e.g. via APU 306); add supplemental content retrieved from another device (e.g., a content server, cloud servers, internet servers/databases, etc.) to the broadcasted or streaming digital content based on the processing of the broadcasted or the streaming digital content with the one or more trained AI/NN models (e.g., via OPU 312); and provide the broadcasted or streaming digital content with the supplemental content retrieved from another device as output (e.g., as shown at 322). In example implementations, the broadcasted or streaming digital content can include television audio/video content, streaming audio/video content from a streaming server or application, internet audio/video, local broadcasted content (e.g., from another device such as a camera), or otherwise depending on the desired implementation.

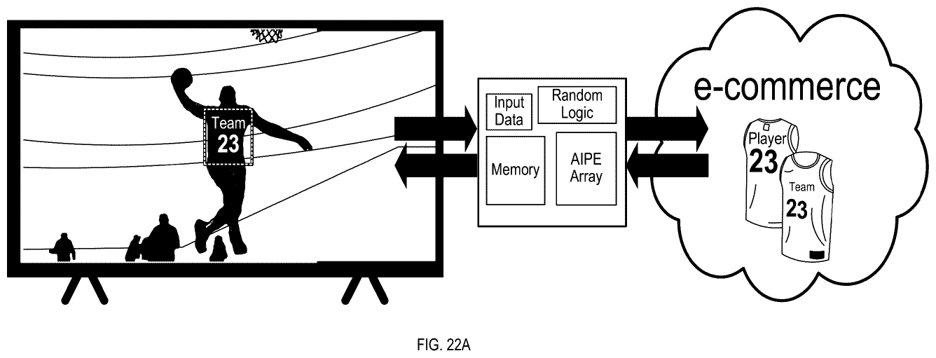

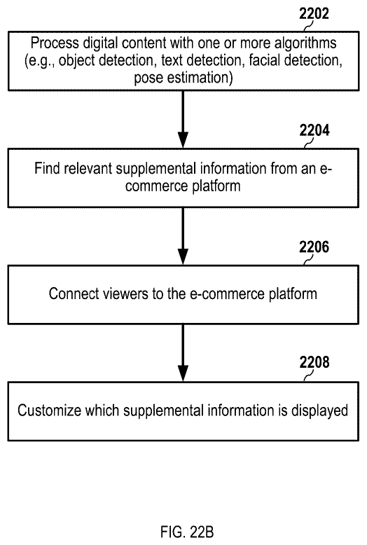

Depending on the desired implementation, the supplemental content retrieved from the another device can involve one or more social media posts retrieved from an internet connection as illustrated in FIG. 21A.

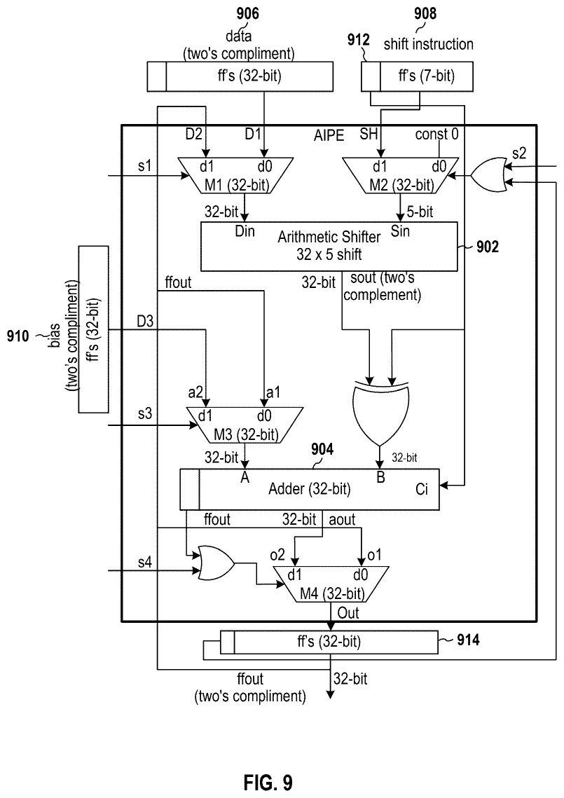

Depending on the desired implementation, the SoC 302 can be configured to process the broadcasted or streaming digital content with the one or more trained AI/NN models through use of logical shift operations executed by one or more shifter circuits in the SoC as illustrated in FIG. 9.

Depending on the desired implementation, the add operations corresponding to the process of the broadcasted or streaming digital content with the one or more trained AI/NN models can executed by the one or more shifter circuits or one or more adder circuits in the SoC as described with respect to FIG. 9.

Depending on the desired implementation the SoC is configured to process the broadcasted or streaming digital content with the one or more trained AI/NN models through use of logical shift operations executed by a field programmable gate array (FPGA) or one or more hardware processors as described with respect to FIG. 9.

Depending on the desired implementation, the edge system can be a television device, wherein the broadcasted or streaming digital content is television audio/video data as illustrated in FIG. 8A. In such an example implementation, the SoC can be configured to provide the output to a display of the television device, such as an LCD/OLED panel.

Depending on the desired implementation, the edge system can be a set top box, wherein the broadcasted or streaming digital content is television audio/video data as illustrated in FIG. 8B. In such an example implementation, the SoC is configured to provide the output to a television device connected to the set top box.

Depending on the desired implementation the edge system is a streaming device; wherein the broadcasted or streaming digital content is television audio/video data as illustrated in FIG. 8C. In such an example implementation, the SoC is configured to provide the output to a television device connected to the streaming device.

Depending on the desired implementation, the edge system can be connected to a first device configured to provide the broadcasted or streaming digital content (e.g., such as a set top box, a content server, etc.); wherein the SoC is configured to provide the output to a second device (e.g., a television device, a computer device, etc.) connected to the edge system.

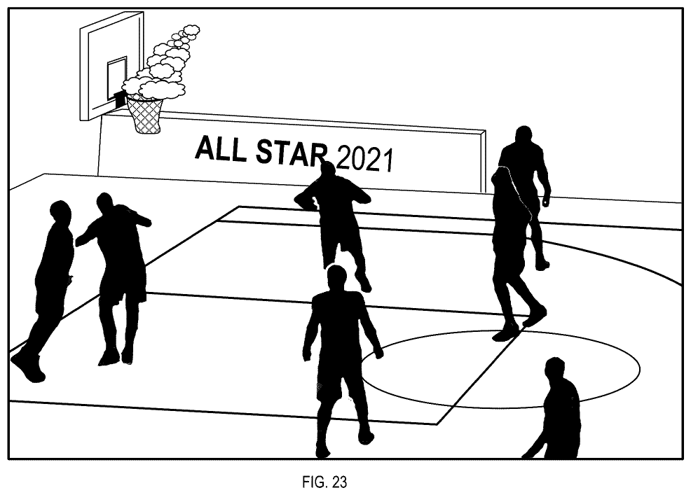

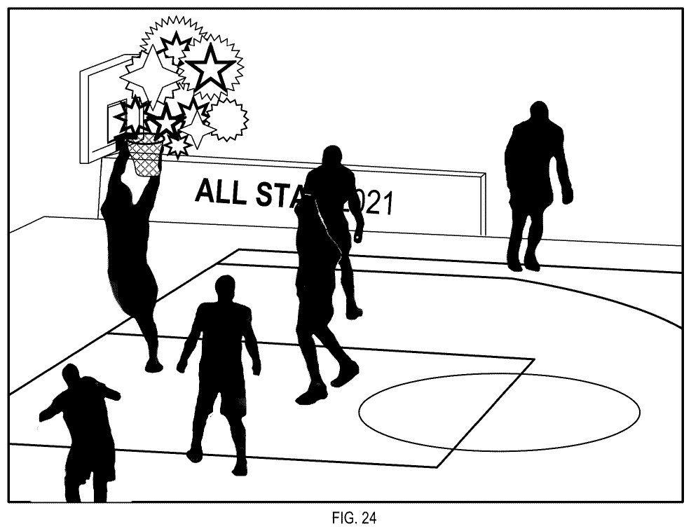

Depending on the desired implementation, the edge system can involve an interface configured to retrieve data from a content server as the supplemental content, wherein the memory is configured to store metadata mapping model output of the one or more trained AI/NN models to supplemental content for retrieval from the content server; wherein the SoC is configured to read the metadata from memory and retrieve corresponding supplemental content from the content server through an interface based on the model output of the one or more trained AI/NN models. In example implementations, the output of the trained AI/NN models can be associated with specific labels that are mapped to specific content to be retrieved in accordance with the desired implementation. For example, for object classification models, the classified objects can be mapped to desired content to be retrieved (e.g., classification of basketball can retrieve an image of a fireball as illustrated in FIG. 23). Other mappings are also possible depending on the model used, and the present disclosure is not particularly limited thereto. For example, the metadata can map the model output of the one or more trained AI/NN models to the supplemental content related to objects available for purchase; wherein the SoC is configured to read the metadata from memory and retrieve corresponding ones of the objects available for purchase from the content server through the interface, the corresponding ones of the objects available for purchased provided based on the model output of the one or more trained AI/NN models as illustrated in FIG. 22A.

Depending on the desired implementation, the one or more trained AI/NN models can involve a facial recognition model configured to conduct facial recognition on the broadcasted or streaming digital content; wherein the SoC is configured to add the supplemental content based on identified faces from the facial recognition.

As described with respect to FIG. 9, the edge system can involve an interface configured to retrieve one or more log quantized parameters corresponding to the one or more AI/NN models from a server (e.g., a cloud server, a content server, or any server or device configured to train the AI/NN models and provide the corresponding parameters) and store the one or more log quantized parameters in the memory; wherein the SoC is configured to process the broadcasted or streaming digital content with the one or more trained AI/NN models through use of the one or more log quantized parameters.

In example implementations as illustrated in FIGS. 8A to 8D based on FIGS. 3A and 3B, there can be a television-implemented method, the method involving intaking a television broadcast; executing one or more trained neural network models through one or more neural network operations of a trained neural network in connection with the television broadcast; adding one or more overlays to the television data based on one or more classified objects from the image data; and displaying the television data with the added overlays on a display of the television. Depending on the desired implementation, such television-implemented methods can further involve retrieving data from a content server as the one or more overlays based on the one or more classified objects from the image data, and/or retrieving one or more log quantized parameters data from an external device and storing the one or more log quantized parameters in memory.

Depending on the desired implementation, the edge system can involve a memory configured to store an object detection/classification model in a form of a trained neural network represented by one or more log quantized parameter values, the object detection/classification model configured to detect/classify one or more objects on image data through one or more neural network operations according to the log quantized parameter values of the trained neural network; and a system on chip (SoC), configured to intake the image data; execute the object detection model to classify the one or more objects from the image data through the one or more neural network operations, the one or more neural network operations executed by logical shift operations on the image data based on the one or more log quantized parameter values read from the memory; add one or more overlays to the image data based on the classified one or more objects from the image data; and provide the image data with the added overlays as output.

Depending on the desired implementation, there can be a method for an edge system, which can involve executing, on received image data, an object detection/classification model configured to classify/detect one or more objects on image data through one or more neural network operations according to log quantized parameter values of a trained neural network, the executing comprising executing logical shift operations on the image data based on the log quantized parameter values; adding one or more overlays on the image data based on the classified one or more objects; and providing the image data with the added one or more overlays as output.

FIG. 9 illustrates an example of an AI Processing Element (AIPE) for processing digital content by executing various neural network operations, in accordance with an example implementation. The AIPE of FIG. 9 may comprise an arithmetic shift architecture in order to process the digital content by executing various neural network operations such as convolution, batch normalization, parametric ReLU, recurrent neural network, and fully connected neural network operations. However, the disclosure is not intended to be limited to the arithmetic shift architecture disclosed herein. In some aspects, the AIPE may include adders or additional shifters to process the digital content. The AIPE of FIG. 9 utilizes an arithmetic shifter 902 and an adder 904 to process neural network operations, such as but not limited to convolution, dense layer, parametric ReLU, max pooling, addition, and/or multiplication. The arithmetic shifter 902 receives, as input, data 906 and shift instruction 908 derived from a log-quantized parameter. The data 906 may comprise 32-bit data based in two's compliment, while the shift instruction 908 derived from the log-quantized parameter may comprise 7-bit data. For example, the arithmetic shifter 902 may comprise a 32-bit arithmetic shifter. The arithmetic shifter 902 shifts the data 906 based on the shift instruction 908 derived from the log-quantized parameter. The output of the arithmetic shifter 902 goes through a two's compliment architecture and is added with a bias 910. In some aspects, the bias 910 may comprise a 32-bit bias. The adder 904 receives, as input, the output of the arithmetic shifter 902. The output of the XOR operation between the output of the arithmetic shifter 902 and the sign bit 912 is then fed into the adder 904. The adder 904 receives the bias 910, the output of the XOR operation between the output of the arithmetic shifter 902 and the sign bit 912 as the carry-in input to add together. The output of the adder 904 is fed into a flip flop 914. The data of the flip flop 914 is fed back into the AIPE of FIG. 9. For example, the output of the flip flop 914 is fed into a multiplexor M1 and is data multiplexed with the data 906. The output of the flip flop 914 is also fed into a bias multiplexor M3 and is multiplexed with the bias 910. The output of the flip flop 914 is also fed into an output multiplexor M4 and is multiplexed with the output of the adder 904. The output of the flip flop 914 may be in the form of two's compliment. A sign bit of the data of the flip flop 914 is also fed back into the AIPE to control the parameter multiplexor M2. For example, the sign bit of the data of the flip flop 914 is fed into an OR operator together with S2 signal, where the result of the OR operation is fed into a multiplexor M2 that multiplexes the shift instruction 908 and a constant 0 signal.

The example of FIG. 9 discloses an AIPE that utilizes an arithmetic shift architecture to process the digital content. However, the disclosure is not intended to be limited to the aspects disclosed herein. The AIPE may comprise different architectures involving logical shift (e.g., via arithmetic shift, binary shift, etc.) that utilize various neural network operations to process the digital content, for example, as disclosed in PCT Application no. PCT/US22/27035, entitled “IMPLEMENTATIONS AND METHODS FOR PROCESSING NEURAL NETWORK IN SEMICONDUCTOR HARDWARE” and filed on Apr. 29, 2022, the disclosures of which are expressly incorporated by reference herein in its entirety. In such example implementations, the adder circuits may also be replaced with shifter circuits to facilitate the desired implementation.

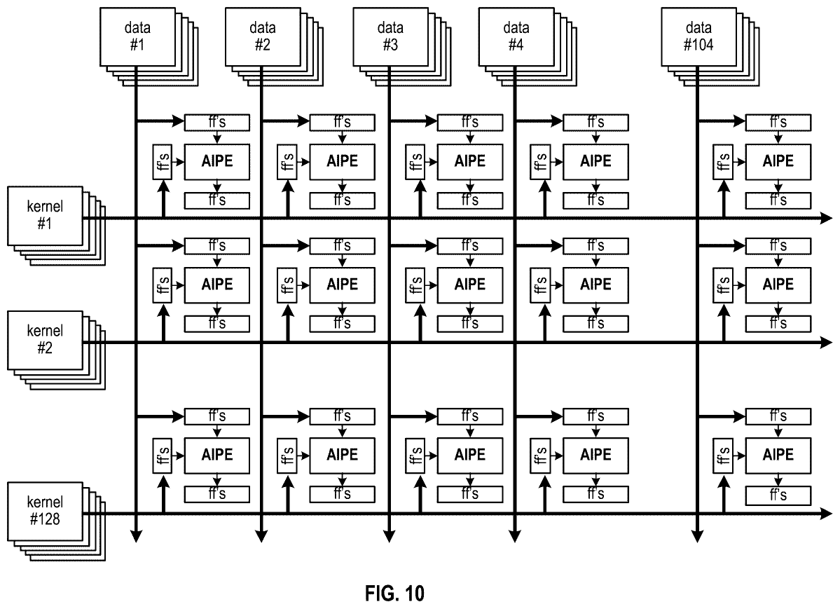

FIG. 10 illustrates an example of an AIPE array, in accordance with an example implementation. In the example of FIG. 10, the AIPE array comprises a plurality of AIPE's where data and parameters (kernels) are inputted into the AIPE's to perform the various neural network operations to process digital content, as disclosed herein. The AIPE architecture may comprise shifters and logic gates, but may be configured to utilize other elements and the disclosure is not intended to be limited the examples disclosed herein. Examples disclosed herein comprise 32-bit data with 7-bit shift instruction derived from the parameter, where data can be from 1-bit to N-bit and the shift instruction can be from 1-bit to M-bit parameter, where N and M are any positive integer. Some examples include a 32-bit shifter; however, the number of shifters may be more than one and may vary from one shifter to O number of shifters where O is a positive integer. In some instances, the architecture comprises data 128-bit, shift instruction derived from the log-quantized parameter 8-bit, and 7 shifters connected in series—one after another. Also, the logic gates that are shown in herein are a typical set of logic gates which can change depending on a certain architecture.

In some instances, the AIPE architecture may utilize shifters, adders, and/or logic gates. Examples disclosed herein comprise 32-bit data with 7-bit shift instruction derived from the log-quantized parameter, data can be from 1-bit to N-bit and the shift instruction can be from 1-bit to M-bit data, where N and M are any positive integer. Some examples include one 32-bit shifter, and one 32-bit two input adder, however the number of shifters and adders may be more than one and may vary from one shifter to O number of shifters and one adder to P number of adders where O and P are a positive integer. In some instances, the architecture comprises data 128-bit, shift instruction 8-bit, and 2 shifters connected in series, and 2 adders connected in series—one after another.

The AIPE architecture disclosed herein may be implemented with shifters and logic gates where shift operations replace multiplication and addition/accumulate operations. The AIPE architecture disclosed herein may also be implemented with shifters, adders, and logic gates where shift operations replace multiplication and addition/accumulate operations. However, in some aspects, the AIPE architecture may be comprised of multipliers, adders, and/or shifters.

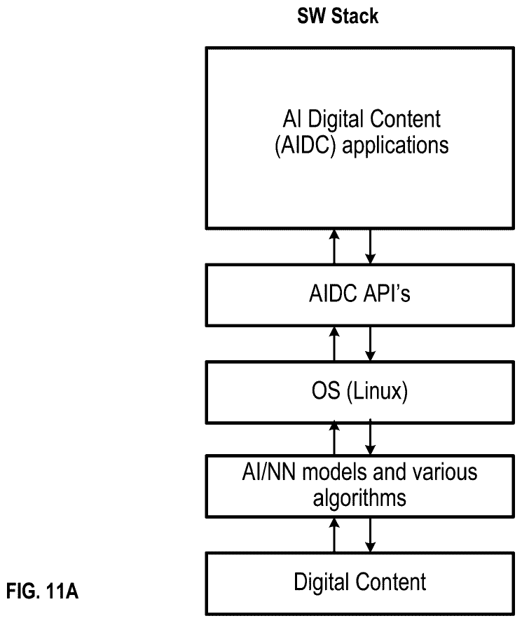

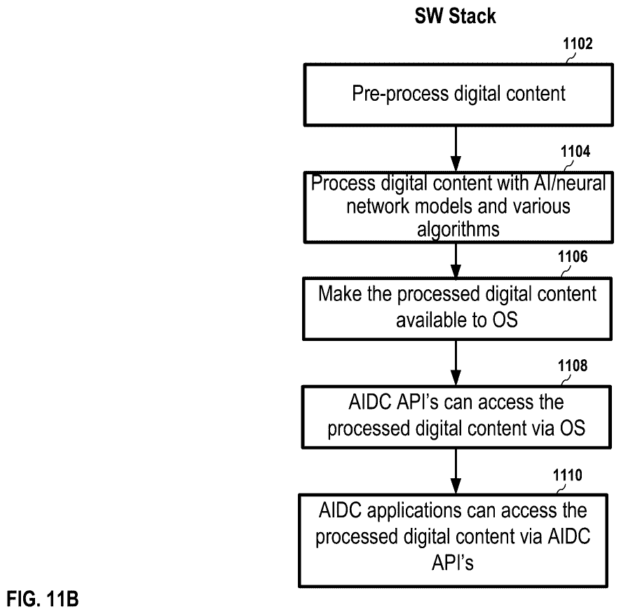

FIGS. 11A and 11B illustrate an example of a software stack for AI digital content applications using processed digital content, in accordance with an example implementation. Specifically, FIG. 11B illustrates a flow of the software stack for AI digital content applications using the processed digital content used in the example for FIG. 11A. At 1102, the flow pre-processes the digital content (down-sample, up-sample, crop, etc) to be used by various algorithms. At 1104, the flow processes the digital content using the AI/neural network models and various algorithms such as, but not limited to, object detection, classification, recognition, speech recognition, natural language processing. At 1106, the flow makes the processed digital data and the information from processing the digital data available to an operating system (OS). At 1108, AI Digital Content API's can access the processed digital data via the operating system. At 1110, AIDC applications can access the processed digital data through the AIDC API's and interact with the viewers/users of the applications to provide useful services and functions.

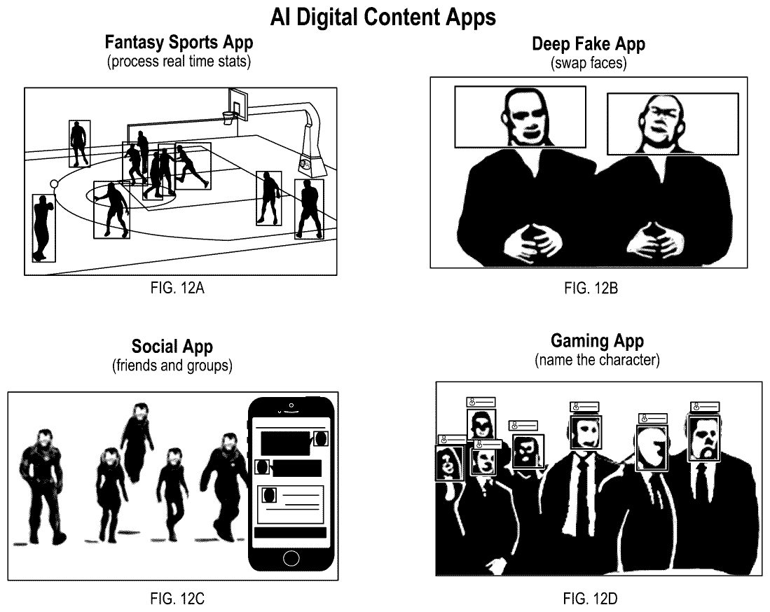

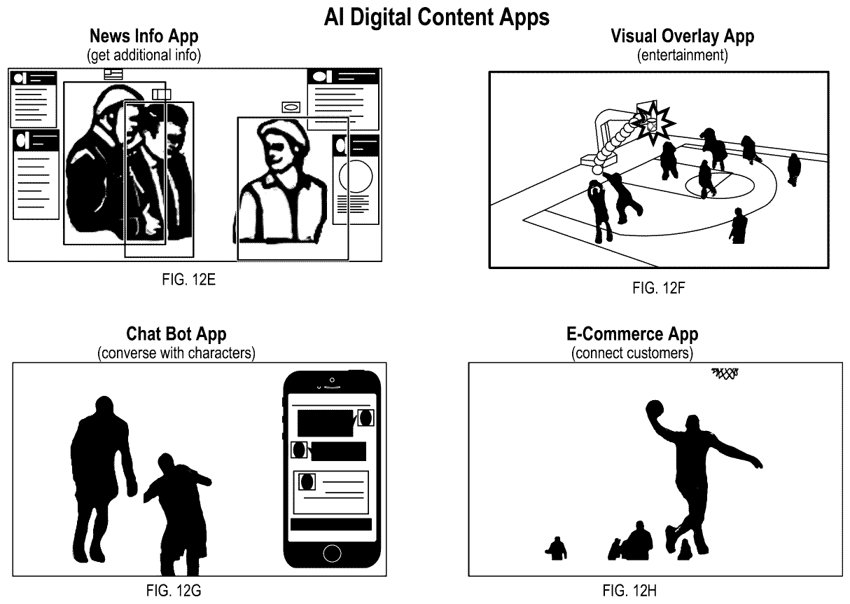

FIGS. 12A-12H illustrate example of applications that may utilize processed digital content, in accordance with example implementations. In FIG. 12A, AI/neural network models and other algorithms process a sports game digital content to identify at least one or more of players, teams, objects or texts associated with the sporting event and supplement any relevant information found in the cloud/internet/system/database/people such as real time statistics, historical statistics, team statistics, expert opinions. A fantasy sports application can be developed based on the processed digital content along with the supplemental information found. In FIG. 12B, AI/neural network models and other algorithms process a digital content to identify an individual such as an actor. A deep fake application may utilize the processed digital content for anyone to swap out the identified individual within the processed digital content with any other person. In FIG. 12C, AI/neural network models and other algorithms process a digital content to identify persons, objects, scenes, and texts and supplement any relevant information found in the cloud/internet/system/database/people about the digital content. A social application may utilize the processed digital content so that friends or any group of individuals can connect and interface with each other via the processed digital content such as voting what actions to take or deciding to put certain type of image overlay on the processed content. In FIG. 12D, AI/neural network models and other algorithms process digital content to identify one or more people that appear in the digital content. A gaming application may utilize the processed content to generate a game or interactive entertainment application in connection with the processed content. For example, the gaming application may provide a prompt to allow viewers to name people that appear on the content. In FIG. 12E, AI/neural network models and other algorithms process a digital content to identify people, events, and texts. A news application may utilize the processed digital content and obtain news articles or stories related to the people, events, and texts that are identified and connect the articles or stories to the processed content. In FIG. 12F, AI/neural network models and other algorithms process a digital content to identify people, objects, and texts. A visual overlay application may utilize the processed digital content for viewers to interact with the processed digital content. For example, the visual overlay application may allow users to put any visual overlay on the processed content. In FIG. 12G, AI/neural network models and other algorithms process a digital content to identify all characters in the digital content. A Chat bot application may utilize the processed digital content for viewers to have a dialogue with the characters identified in the digital content. In FIG. 12H, AI/neural network models and other algorithms process a digital content to identify any objects that are associated with e-commerce platform. An e-commerce application may utilize the processed digital content to connect the appropriate e-commerce platform to the views of the processed digital content. For example, the digital content may comprise a sporting event (e.g., basketball game) and the e-commerce application may allow users to purchase sporting apparel of the identified teams or allow users to purchase tickets to an upcoming sporting event.

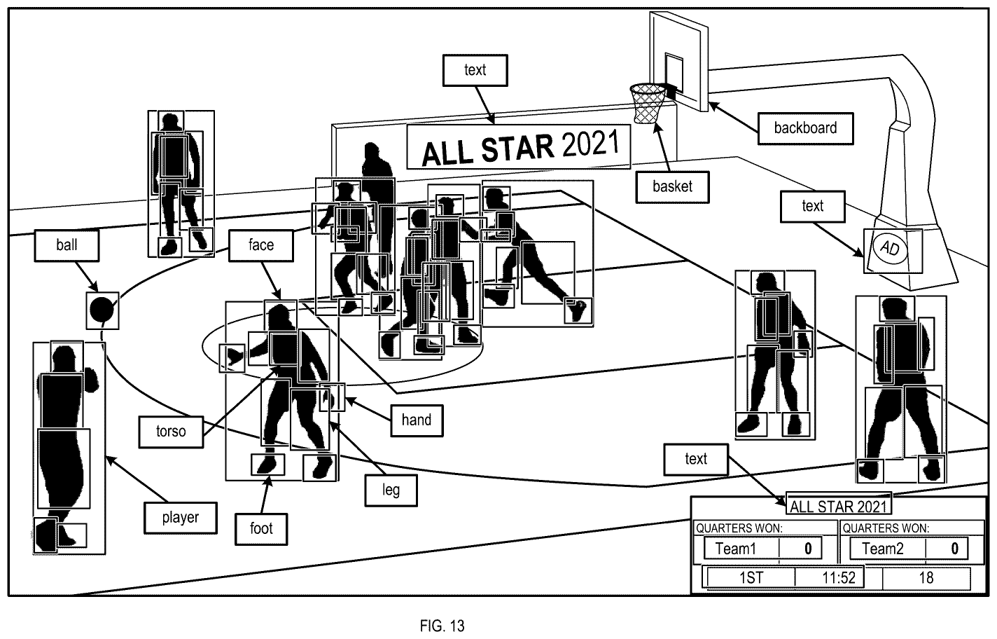

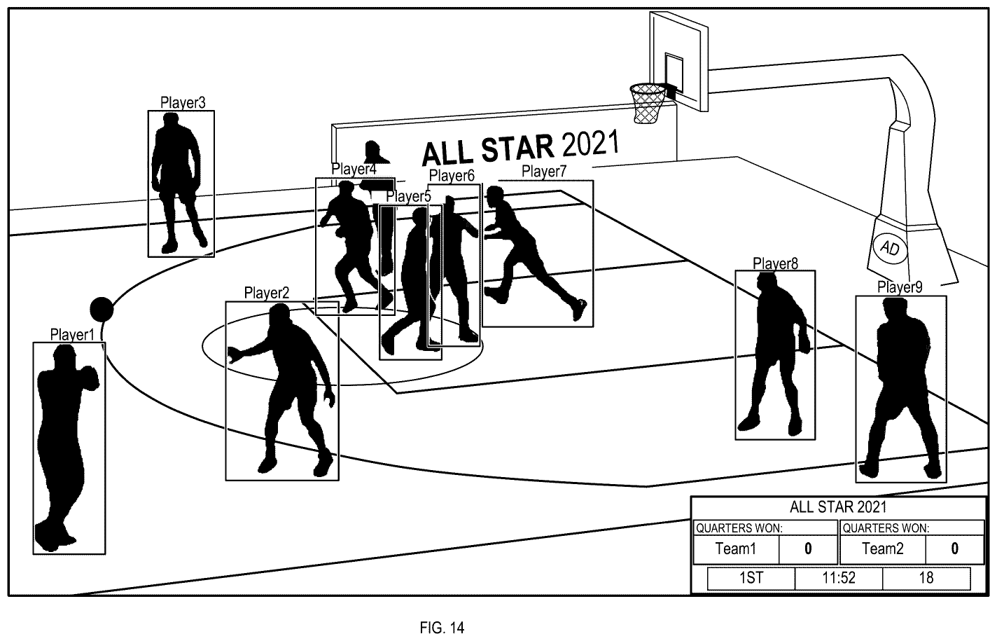

FIG. 13 illustrates an example of a digital content processed with detection algorithms, in accordance with an example implementation. The detection algorithm may detect objects and people within the digital content. For example, the detection algorithm may detect basketball players, body parts (e.g., hand, face, leg, foot, torso, etc.), basketball, backboard, and a basket. The detection algorithm may also detect text within the digital content, such as advertisements or scoring of players/teams involved in the digital content. A people recognition algorithm, such as facial recognition or jersey number recognition algorithm, upon detection of people may further process the detected people in an effort to identify the player, for example, as shown in FIG. 14. In FIG. 14, the recognition algorithm may identify the one or more players and provide the name of the player within the digital content being processed.

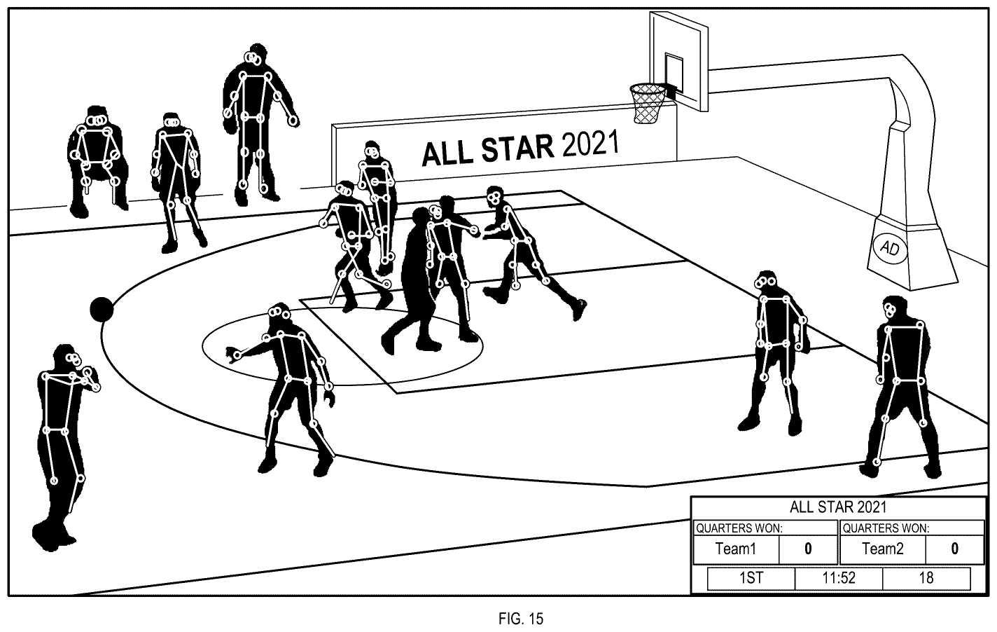

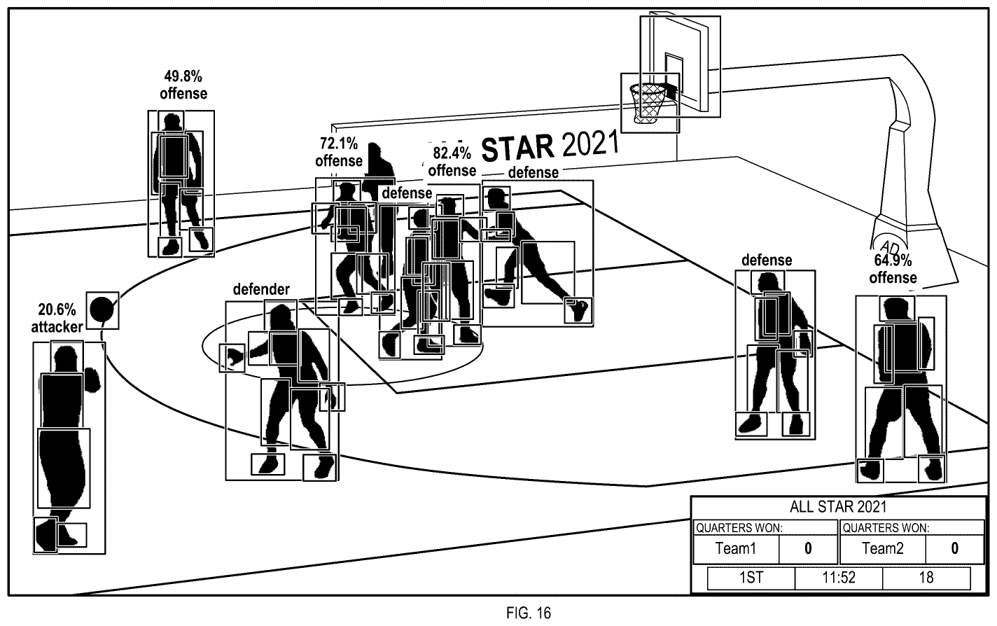

FIG. 15 illustrates an example of a digital content processed with pose estimation algorithm, in accordance with an example implementation. In the example of FIG. 15, the pose estimation algorithm may detect a pose of people within the digital content. Useful information about the digital content that is processed with the pose estimation algorithm can be attained such as a player is standing or sitting, a player is walking, a player is passing the ball, or a player is watching the ball. For example, in a real-time sporting event, such as a basketball game, useful information gathered by processing the digital content with detection algorithm, recognition algorithm, and/or pose estimation algorithm can be used to analyze more about the content such as if a player is on the offense (attacker) or a payer is on the defense (defender) as shown in FIG. 16.

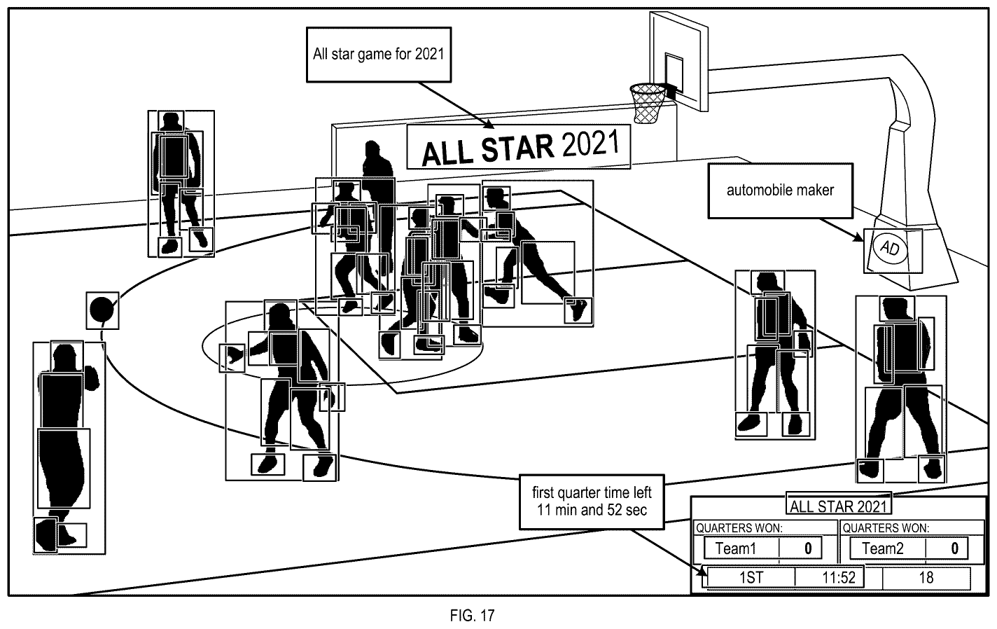

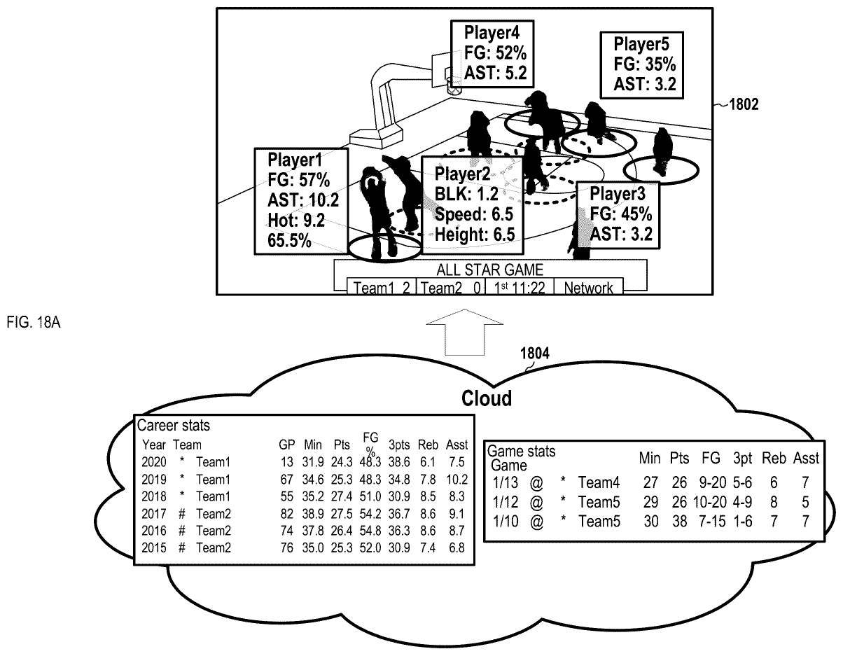

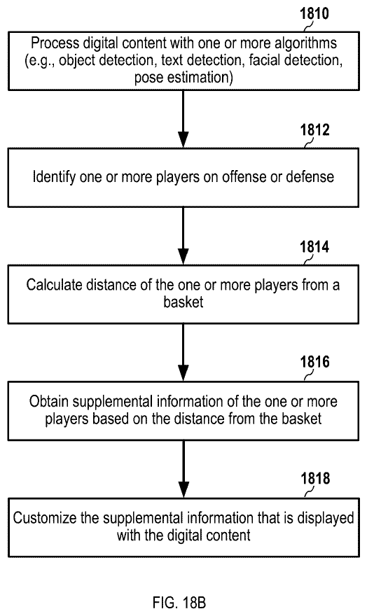

FIG. 17 illustrates an example of a digital content processed with text detection algorithm and natural language processing algorithm, in accordance with an example implementation. In the example of FIG. 17, the text detection algorithm may detect text within the digital content. For example, the detection algorithm may detect the texts in one or more advertisements within the digital content (e.g., automobile makers, etc.). In another example, the detection algorithm may detect text related to the digital content, such as information related to score or time remaining in the real-time event. After various texts are detected using the text detection algorithm, natural language processing algorithms can be used to gain more insightful information on the detected texts such as attaining the maker of automobile or the information about the basketball game (e.g., score, which quarter, time left in the game, etc.).

FIGS. 18A and 18B illustrate an example of processed digital content supplemented with relevant information from the cloud/internet/system/database/people, in accordance with an example implementation. Specifically, FIG. 18B illustrates a flow of the processed digital content supplemented with relevant information used in the example for FIG. 18A. At 1810, the flow processes digital content using one or more algorithms. The digital content (e.g., basketball related content) may be processed with one or more algorithms, such as but not limited to object detection, text detection, facial detection, pose estimation, or the like. Object detection algorithms may detect players, a basketball, basket, backboard within the digital content. Text detection algorithms may detect text within the digital content (e.g., text or numbers on a uniform). Facial recognition algorithms may identify the players or people within the digital content. Pose estimation algorithms may detect the pose of the players within the digital content. At 1812, the flow identifies one or more players on offense or defense. For example, the one or more algorithms may identify the players on offense or defense based on which player(s) have the basketball. At 1814, the flow calculates a distance of the one or more players from the basket. The one or more algorithms may calculate the distance of each player from the basket. At 1816, the flow obtains supplemental information of the one or more players. For example, the supplemental information of the one or more players may be based on the distance the one or more players are from the basket. The supplemental information of each player may include field goal percentage based on the distance from the basket, or other statistical information in relation to the player's distance from the basket. The supplemental information of each player may be obtained from the cloud/internet/system/database/people. At 1818, the flow customizes the supplemental information that is displayed with the digital content. For example, viewers may customize the supplemental information that is displayed on the display device in connection with the digital content. The annotated digital content 1802 with the supplementary information from the cloud/internet/system/database/people may include information such as statistical information retrieved from the cloud 1804 for the players detected within the digital content. Viewers may have options to display which supplemental information found in the cloud 1804 on their devices depending on their preference. After an AI edge device processes the digital content with various algorithms including, but not limited to, object detection algorithm, recognition algorithm, text detection algorithm, natural language processing algorithm, and supplements the digital content with the relevant information from the cloud/internet/system/database/people, viewers can decide what supplemental information to display, where in the device to display, when to display on their device.

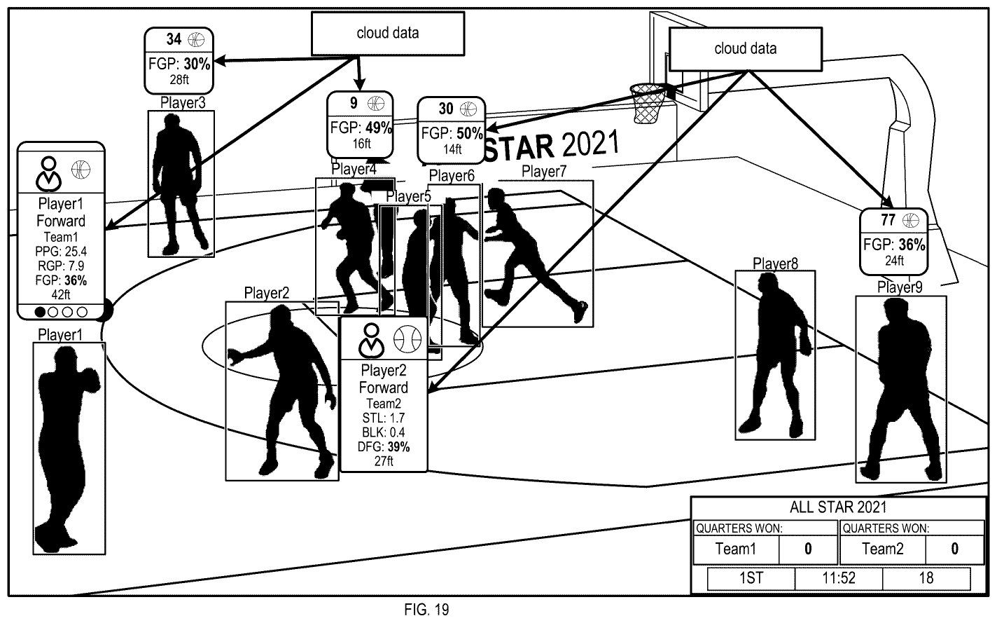

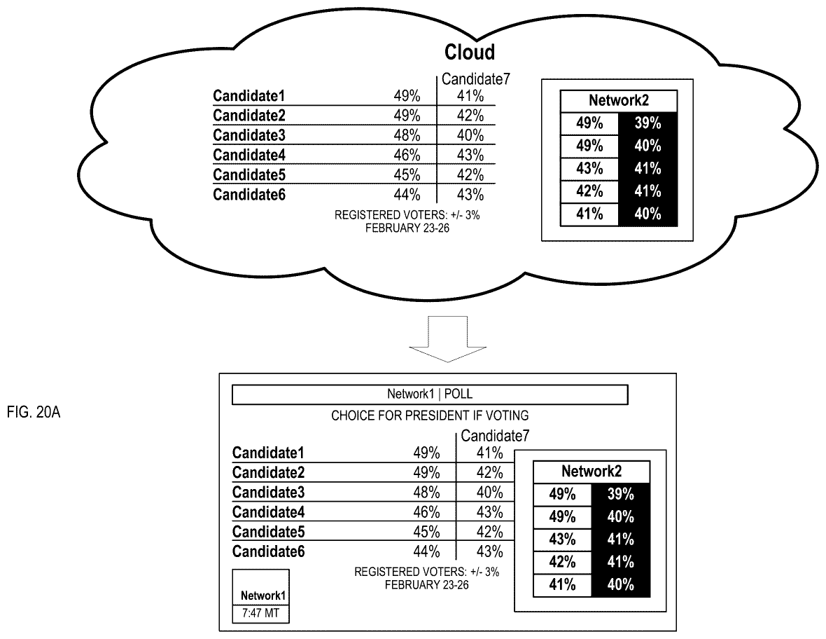

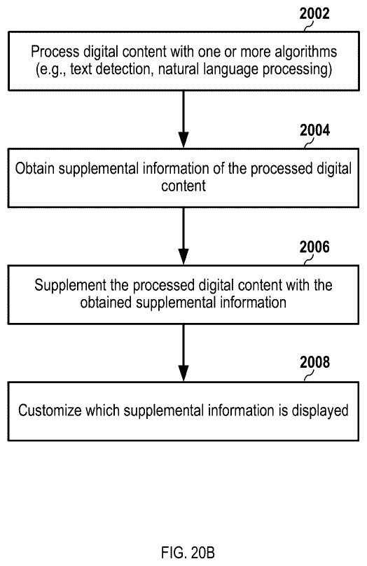

FIG. 19 illustrates an example of processed digital content supplemented with the relevant information from the cloud/internet/system/database/people, in accordance with an example implementation. In the example of FIG. 19, relevant supplemental information found from the cloud/internet/system/database/people may be overlaid on the digital content for viewing. The digital content in FIG. 19 can be processed with detection algorithms to detect players, the basket, and the basketball. After detecting players and the basket, one or more algorithms can be used to process each player to attain the distance of each player from the basket. Once the distance of the player to the basket is attained, a relevant information such as the player's field goal percentage (FGP) given the distance from the basket can be searched and attained from the cloud/internet/system/database/people. This distance specific field goal percentage for the player can then be supplemented to the digital content to be ready for the viewers to display such information at any time they choose.

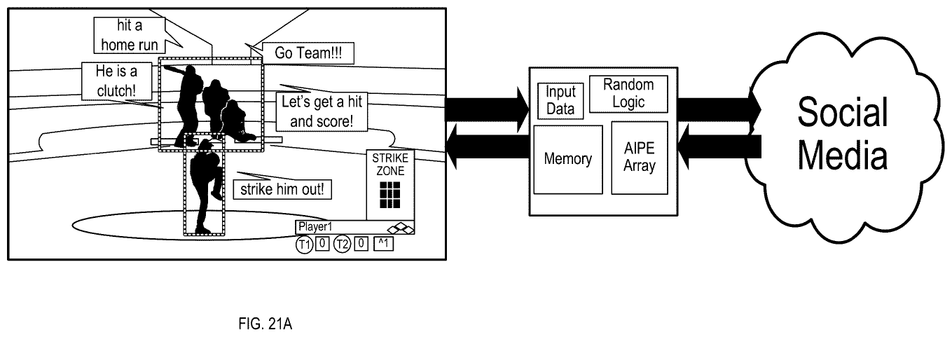

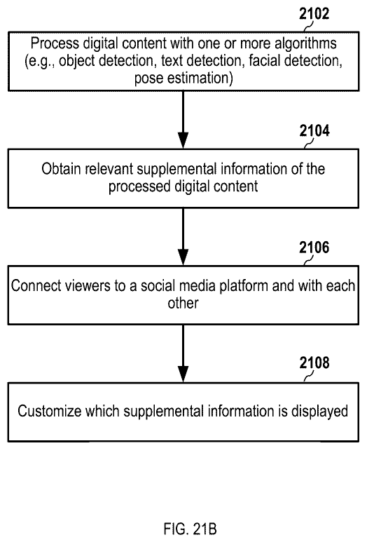

FIGS. 20A and 20B illustrate an example of processed digital content supplemented with relevant information from the cloud/internet/system/database/people in accordance with an example implementation. Specifically, FIG. 20B illustrates a flow of the processed digital content supplemented with the relevant information used in the example for FIG. 20A. At 2002, the flow processes digital content with one or more algorithms. For example, the digital content (e.g., news content) may be processed with various algorithms, such as text detection algorithms that detect text. The detected text may be processed with natural language processing algorithms. In FIG. 20A, the digital content such as news content is processed with text detection and natural language processing algorithms to identify the content as a polling result of an election for various candidates. At 2004, the flow obtains supplemental information of the processed digital content. Once the digital content is processed to attain the information aforementioned, any relevant supplemental information can be searched and found in the cloud/internet/system/database/people such as other polling information done by a different pollster. At 2006, the flow supplements the processed digital content with the obtained supplemental information. At 2008, the flow customizes which supplemental information to display. For example, users can decide to display the supplemental information on their display device when they choose to.

FIGS. 21A and 21B illustrate an example of processed digital content supplemented with relevant information from a social media platform, in accordance with an example implementation. Specifically, FIG. 21B illustrates a flow of the processed digital content supplemented with the relevant information used in the example for FIG. 21A. At 2102, the flow processes digital content with one or more algorithms. The one or more algorithms may process the digital content (e.g., baseball content) with various algorithms, such as object detection algorithms that detect one or more baseball players. Facial recognition algorithms may detect players based on the players face. Text recognition algorithms may detect a jersey number of the player to identify the baseball players. In the example of FIG. 21A, the digital content is processed with various algorithms to detect the pitcher, hitter, catcher, and umpire in a baseball game. A facial recognition algorithm and/or jersey number recognition algorithm can be used to identify all the players in the digital content. At 2104, the flow obtains relevant supplemental information of the processed digital content. For example, the relevant information from the cloud/internet/system/database/people (in this case social media platform in the internet and/or people connected to the internet or cloud) can be found and supplemented to the digital content that is processed. At 2106, the flow connects viewers to a social media platform and with each other. In FIG. 21A, posting from a social media or real-time comments from people who are watching the game can be supplemented to the digital content. At 2108, the flow customizes which supplemental information to display. For example, viewers can decide to overlay the supplemental information on the digital content. Such overlay is called social overlay since the supplemental information comes from social interaction with people or from a social media platform.

FIGS. 22A and 22B illustrate an example of processed digital content supplemented with relevant information from the cloud/internet/system/database/people, in accordance with an example implementation. Specifically, FIG. 22B illustrates a flow of the processed digital content supplemented with the relevant information used in the example for FIG. 22A. At 2202, the flow processes the digital content with one or more algorithms. The one or more algorithms may process the digital content (e.g., basketball content) with various algorithms, such as object detection algorithms that detect one or more players. Facial recognition algorithms may detect players based on the players face. Text recognition algorithms may detect a jersey number of the player to identify the players. In FIG. 22A, the digital content is processed with various algorithms to detect a basketball player with a jersey, shoes, and basketball. Recognition algorithms can be used to identify the player and the player's team. At 2204, the flow finds relevant supplemental information from an e-commerce platform. In this example, a relevant supplemental information found in the cloud/internet/system/database/people can be related to e-commerce platform such as where to buy the jersey, shoes, or basketball or the link to some e-commerce website, or links to the advertisement of such products. At 2206, the flow connects viewers to the e-commerce platform. At 2208, the flow customizes which supplemental information to display. After the digital content is supplemented with the relevant supplemental information, the viewers can decide to display and use such information to order the products or check for pricing or availability of such products. Advertisers and e-commerce entities can have a direct access to consumers via the processed digital content.

FIG. 23 illustrates an example of customized digital content using processed information from the digital content, in accordance with an example implementation. In some aspects, upon the detection of an object within the processed digital content, the detected object may be modified to include a customizable overlay. For example, FIG. 23 provides an example of a real-time basketball game where the basketball has been detected. The basketball may be selected to include the customizable overlay, which in the example of FIG. 23 includes an overlay comprised of fire and smoke. In some instances, the basketball having the overlay of fire and smoke may be utilized to indicate that the shooter of the basketball is having a good game, such that the player is “on fire”. However, in some instances, many different overlays may be used in conjunction with the detected object, and the disclosure is not intended to be limited to an overlay comprised of fire and smoke.

FIG. 24 illustrates an example of customized digital content using processed information from the digital content, in accordance with an example implementation. In some aspects, upon the detection of an occurrence of an event involving a detected object may result in the displaying of a customizable overlay. For example, FIG. 24 provides an example of a real-time basketball game where the basketball has been detected. During the real-time basketball game, a player may slam dunk the detected basketball, such that the occurrence of the basketball being slam dunked is detected and an overlay is provided over the detected basketball. In the example of FIG. 24, the occurrence of the slam dunking of the detected basketball may provide for an overlay comprised of explosions or fireworks. However, in some instances, many different overlays may be used in conjunction with the detection of an occurrence of an event involving the detected object, and the disclosure is not intended to be limited to an overlay comprised of explosions or fireworks.

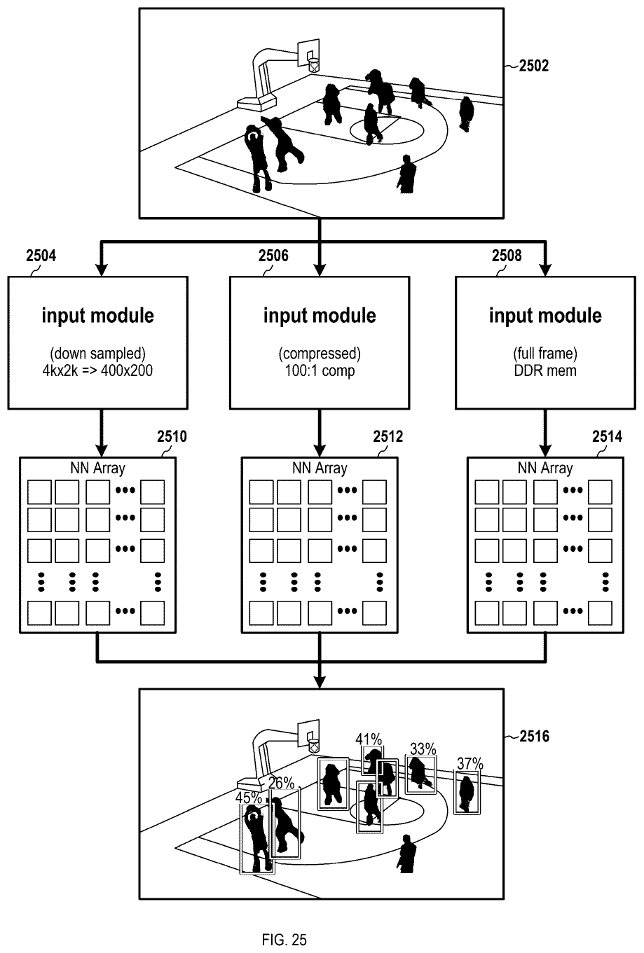

FIG. 25 illustrates an example of processing of various input image pre-processing methods before processing it with various algorithms in accordance with an example implementation. The digital content 2502 may comprise raw data. The raw data may comprise high resolution (e.g., 4K or high definition) which may comprise too much information to be effectively or efficiently processed. As such, the raw data may be provided to an input module 2504, 2506, or 2508 to modify the raw data. Modification of the raw data may allow for effective or efficient processing. In some aspects, the input module 2504 may receive the raw data and down sample the raw data. For example, the down sampling of the resolution may reduce the resolution of the raw data to a much lower resolution, such as but not limited to 400×200. In some aspects, the input module 2506 may receive the raw data and compress the raw data by a compression factor of 100:1. The compression factor may comprise many different values, such that the disclosure is not intended to be limited to a compression factor of 100:1. In some aspects, the input module 2508 may receive the raw data and does not down sample or compress the raw data, such that the input module 2508 comprises a full frame version of the raw data. Input module 2504 may be utilized to down sample the raw data in instances where the raw data has a high resolution, such that processing of the high resolution raw data would take up too much time and processing resources. Input module 2506 may be utilized to compress the raw data in instances where the raw data has a high resolution, such that processing of the high resolution raw data would take up too much time and processing resources. Input module 2508 may be utilized to provide a full frame of the raw data in instances where AI accuracy is important or essential, such that processing resources are available to process the full frame of the raw data. The output of the input modules is then provided to a respective neural network array 2510, 2512, 2514 for processing. The output of the respective neural network array 2510, 2512, 2514 can be used to supplement the digital content 2516.

The present disclosure is not intended to be limited to the implementations discussed herein, other implementations are also possible. The AI SoC proposed herein can also be extended to other edge or server systems that can utilize such functions, including mobile devices, surveillance devices (e.g., cameras or other sensors connected to central stations or local user control systems), personal computers, tablets or other user equipment, vehicles (e.g., ADAS systems, or ECU based systems), Internet of Things edge devices (e.g., aggregators, gateways, routers), AR/VR systems, smart homes and other smart system implementations, and so on in accordance with the desired implementation.

Some portions of the detailed description are presented in terms of algorithms and symbolic representations of operations within a computer. These algorithmic descriptions and symbolic representations are the means used by those skilled in the data processing arts to convey the essence of their innovations to others skilled in the art. An algorithm is a series of defined steps leading to a desired end state or result. In example implementations, the steps carried out require physical manipulations of tangible quantities for achieving a tangible result.

Unless specifically stated otherwise, as apparent from the discussion, it is appreciated that throughout the description, discussions utilizing terms such as “processing,” “computing,” “calculating,” “determining,” “displaying,” or the like, can include the actions and processes of a computer system or other information processing device that manipulates and transforms data represented as physical (electronic) quantities within the computer system's registers and memories into other data similarly represented as physical quantities within the computer system's memories or registers or other information storage, transmission or display devices.

Example implementations may also relate to an apparatus for performing the operations herein. This apparatus may be specially constructed for the required purposes, or it may include one or more general-purpose computers selectively activated or reconfigured by one or more computer programs. Such computer programs may be stored in a computer readable medium, such as a computer-readable storage medium or a computer-readable signal medium. A computer-readable storage medium may involve tangible mediums such as, but not limited to optical disks, magnetic disks, read-only memories, random access memories, solid state devices and drives, or any other types of tangible or non-transitory media suitable for storing electronic information. A computer readable signal medium may include mediums such as carrier waves. The algorithms and displays presented herein are not inherently related to any particular computer or other apparatus. Computer programs can involve pure software implementations that involve instructions that perform the operations of the desired implementation.

Various general-purpose systems may be used with programs and modules in accordance with the examples herein, or it may prove convenient to construct a more specialized apparatus to perform desired method steps. In addition, the example implementations are not described with reference to any particular programming language. It will be appreciated that a variety of programming languages may be used to implement the techniques of the example implementations as described herein. The instructions of the programming language(s) may be executed by one or more processing devices, e.g., central processing units (CPUs), processors, or controllers.

As is known in the art, the operations described above can be performed by hardware, software, or some combination of software and hardware. Various aspects of the example implementations may be implemented using circuits and logic devices (hardware), while other aspects may be implemented using instructions stored on a machine-readable medium (software), which if executed by a processor, would cause the processor to perform a method to carry out implementations of the present application. Further, some example implementations of the present application may be performed solely in hardware, whereas other example implementations may be performed solely in software. Moreover, the various functions described can be performed in a single unit, or can be spread across a number of components in any number of ways. When performed by software, the methods may be executed by a processor, such as a general purpose computer, based on instructions stored on a computer-readable medium. If desired, the instructions can be stored on the medium in a compressed and/or encrypted format.

Moreover, other implementations of the present application will be apparent to those skilled in the art from consideration of the specification and practice of the techniques of the present application. Various aspects and/or components of the described example implementations may be used singly or in any combination. It is intended that the specification and example implementations be considered as examples only, with the true scope and spirit of the present application being indicated by the following claims.

1. An edge system, comprising:
a memory configured to store one or more trained artificial intelligence/neural network (AI/NN) models; and
a system on chip (SoC), configured to:
intake broadcasted or streaming digital content;
process the broadcasted or streaming digital content with the one or more trained AI/NN models through use of logical shift operations executed by one or more shifter circuits in the SoC;
add supplemental content retrieved from another device to modify the broadcasted or streaming digital content based on the processing of the broadcasted or the streaming digital content with the one or more trained AI/NN models; and
provide the broadcasted or streaming digital content modified with the added supplemental content retrieved from another device as output.

2. The edge system of claim 1, wherein the supplemental content retrieved from the another device comprises one or more social media posts retrieved from an internet connection.

3. (canceled)

4. The edge system of claim 1, wherein add operations corresponding to the process of the broadcasted or streaming digital content with the one or more trained AI/NN models are executed by the one or more shifter circuits in the SoC.

5. The edge system of claim 1, wherein add operations corresponding to the process of the broadcasted or streaming digital content with the one or more trained AI/NN models are executed by one or more adder circuits in the SoC.

6. (canceled)

7. (canceled)

8. The edge system of claim 1, wherein the edge system is a television device;
wherein the broadcasted or streaming digital content is television audio/video data;
wherein the SoC is configured to provide the output to a display of the television device.

9. The edge system of claim 1, wherein the edge system is a set top box;
wherein the broadcasted or streaming digital content is television audio/video data;
wherein the SoC is configured to provide the output to a television device connected to the set top box.

10. The edge system of claim 1, wherein the edge system is a streaming device;
wherein the broadcasted or streaming digital content is television audio/video data;
wherein the SoC is configured to provide the output to a television device connected to the streaming device.

11. The edge system of claim 1, wherein the edge system is connected to a first device configured to provide the broadcasted or streaming digital content;
wherein the SoC is configured to provide the output to a second device connected to the edge system.

12. The edge system of claim 1, further comprising:
an interface configured to retrieve data from a content server as the supplemental content,
wherein the memory is configured to store metadata mapping model output of the one or more trained AI/NN models to supplemental content for retrieval from the content server;
wherein the SoC is configured to read the metadata from memory and retrieve corresponding supplemental content from the content server through an interface based on the model output of the one or more trained AI/NN models.

13. The edge system of claim 12, wherein the metadata maps the model output of the one or more trained AI/NN models to the supplemental content related to objects available for purchase;
wherein the SoC is configured to read the metadata from memory and retrieve corresponding ones of the objects available for purchase from the content server through the interface, the corresponding ones of the objects available for purchased provided based on the model output of the one or more trained AI/NN models.

14. The edge system of claim 1, wherein the one or more trained AI/NN models comprises a facial recognition model configured to conduct facial recognition on the broadcasted or streaming digital content;
wherein the SoC is configured to add the supplemental content based on identified faces from the facial recognition.

15. The edge system of claim 1, further comprising:
an interface configured to retrieve one or more log quantized parameters corresponding to the one or more AI/NN models from a server and store the one or more log quantized parameters in the memory;
wherein the SoC is configured to process the broadcasted or streaming digital content with the one or more trained AI/NN models through use of the one or more log quantized parameters.

16. The edge system of claim 1, wherein the one or more AI/NN models comprises an object classification model configured to classify one or more objects from the broadcasted or streaming digital content.
